(19) United States
(12) Patent Application Publication
(10) Pub. No.: US 2002/0089348 A1
(43) Pub. Date: Jul. 11, 2002

(54) Programmable logic integrated circuit devices including dedicated processor components

(76) Inventor: Martin Langhammer, Poole Dorset (GB)

Correspondence Address: FISH & NEAVE, 1251 AVENUE OF THE AMERICAS, 50TH FLOOR, NEW YORK, NY, 10020-1105, US

(21) Appl. No.: 09/969,977

(22) Filed: Oct. 2, 2001

Related U.S. Application Data
(60) Provisional application No. 60/237,170, filed on Oct. 2, 2000.

(51) Int. Cl. H03K 19/173; G06F 9/00

(52) U.S. Cl. 326/38; 712/226

(57) ABSTRACT

A programmable logic integrated circuit device (“PLD”) includes programmable logic and a dedicated (i.e., at least partly hard-wired) processor object (or at least a high-functionality functional unit) for performing or at least helping to perform tasks that it is unduly inefficient to implement in the more general-purpose programmable logic and/or that, if implemented in the programmable logic, would operate unacceptably or at least undesirably slowly. The processor object includes an operating portion and a program sequencer that retrieves or at least helps to retrieve instructions for controlling or at least partly controlling the operating portion. The processor object may also include an address generator and/or a multi-ported register file for generating or at least helping to generate addresses of data on which the operating portion is to operate and/or destinations of data output by the operating portions. Examples of typical operating portions include multiplier-accumulators, arithmetic logic units, barrel shifters, and DSP circuitry of these or other kinds. The PLD may be provided with the capability to allow programs to be written for the device using local or “relative” addresses, and to automatically convert these addresses to actual or “absolute” addresses when the programs are actually performed by the device.

This application claims the benefit of U.S. provisional patent application No. 60/237,170, filed Oct. 2, 2000, which is hereby incorporated by reference herein in its entirety.

### BACKGROUND OF THE INVENTION

This invention relates to programmable logic integrated circuit devices (sometimes referred to herein as “PLDs”), and more particularly to PLDs that include circuitry that is dedicated to performing specific tasks, such as those that are sometimes performed by portions of circuitry often referred to as “processors” or “microprocessors.”

Programmable logic devices (“PLDs”) are well known as is shown, for example, by Jefferson et al. U.S. Pat. No. 5,215,326 and Ngai et al. U.S. pat. application Ser. No. 09/516,921, filed Mar. 2, 2000. PLDs typically include many regions of programmable logic that are interconnectable in any of many different ways by programmable interconnection resources. Each logic region is programmable to perform any of several logic functions on input signals applied to that region from the interconnection resources. As a result of the logic functions it performs, each logic region produces one or more output signals that are applied to the interconnection resources. The interconnection resources typically include drivers, interconnection conductors, and programmable switches for selectively making connections between various interconnection conductors. The interconnection resources can generally be used to connect any logic region output to any logic region input; although to avoid having to devote a disproportionately large fraction of the device to interconnection resources, it is usually the case that only a subset of all possible interconnections can be made in any given programmed configuration of the PLD.

Although only logic regions are mentioned above, it should be noted that many PLDs also now include regions of memory that can be used as random access memory (“RAM”), read-only memory (“ROM”), content addressable memory (“CAM”), product term (“p-term”) logic, etc. There has also been interest in including dedicated (i.e., at least partly hard-wired) microprocessor circuitry in PLDs. Such dedicated microprocessor circuitry can perform at least some of the tasks that are typically associated with microprocessors more rapidly than those tasks can be performed by the general-purpose, programmable logic provided elsewhere on the PLD.

Although having a dedicated, full-featured microprocessor on a PLD may be advantageous in some situations, there are also many situations in which only certain features or functions of a dedicated microprocessor or similar circuitry need to be performed at the greater speeds typically achievable with dedicated, hard-wired circuitry. In these cases, much of the full-featured microprocessor circuitry may be essentially unused and therefore wasted. Indeed, to get to the portion(s) of the full-featured microprocessor circuitry that is (or are) needed for rapid performance of a particular task (or tasks), it may be necessary to route signals through otherwise unused portions of the microprocessor circuitry, thereby wasting time and making operation of the needed portion(s) sub-optimal. In addition, a general-purpose microprocessor may not be the most efficient circuitry for performing certain tasks such as very long instruction word (“VLIW”) processing or digital signal processing (“DSP”), wherein it is frequently desired to perform multiple operations in parallel, unless the microprocessor has been specifically designed to support such operations.

### SUMMARY OF THE INVENTION

In accordance with the present invention a PLD is provided with one or more “processor object circuits” (or “processor objects” or “objects”), in addition to the other kinds of circuitry generally included in PLDs. A processor object is circuitry that is at least partly hard-wired to perform one or a limited number of specific tasks. Thus a processor object is dedicated to performing that task or that limited number of tasks. A processor object is not a full-featured or general-purpose processor or microprocessor, although a processor object may perform some task or subset of the tasks that a full processor or microprocessor is typically capable of performing. Although a processor object is at least partly hard-wired, it may also be programmable or programmably controlled in some respects (e.g., to select among the several tasks that it can perform). A processor object may additionally or alternatively be at least partly dynamically controlled (e.g., by time-varying logic signals on the PLD) to dynamically select among the various tasks that it can perform.

A typical processor object includes instruction sequencer circuitry and operating portion circuitry. A processor object may also include address generator circuitry (which may be or which may include multi-ported register file circuitry). The instruction sequencer circuitry selects or helps to select (from instruction memory) instructions to be performed. The instructions control or help to control operation of the operating portion of the processor object. The address generator selects or helps to select (from data memory) data on which the operating portion is to operate. The address generator may also select destinations (e.g., in data memory) for data output by the operating portion. The address generator may work on address information supplied from the instructions mentioned above.

Circuitry may be provided to automatically convert address information between different address regimes. For example, instructions may be written for a program using data and/or instruction addresses that are “local ” (or “relative”) to that program, without concern for the possibility that these same address values are used in a conflicting way in other programs. These multiple programs may be stored in the programmable logic of the PLD in that form. When a program is to be executed (i.e., at least partly in a processor object on the PLD), interface circuitry is provided for automatically converting the local or relative addresses used in each program to non-conflicting absolute addresses of actual memory locations in the PLD.

Examples of operating portion circuitry that can be provided in a processor object include arithmetic logic units (“ALUs”), multiplier-accumulators (“MACs”), barrel shifters, Galois Field circuitry, and combinations and/or multiple instances thereof. The PLD (especially the processor object(s)) may be adapted to perform very long instruction word (“VLIW”) programs, to perform certain digital signal processing (“DSP”) operations, and/or to perform other similarly sophisticated tasks.

Another aspect of the invention relates to providing PLDs with programmable logic circuitry and at least partly hard-wired, high functionality, functional units adapted to exchange signal information with the programmable logic circuitry. A high functionality functional unit can be like what is referred to above as the operating portion of a processor object, provided that such an operating-portion/functional-unit has more than one function (hence “high functionality”). Examples of high functionality functional units are (1) a multiplier combined with an adder tree or (2) a multiplier combined with an accumulator.

Further features of the invention, its nature and various advantages will be more apparent from the accompanying drawings and the following detailed description.

### BRIEF DESCRIPTION OF THE DRAWINGS

FIG. 1 is a simplified schematic block diagram of representative portions of an illustrative embodiment of a PLD constructed in accordance with the invention.

FIG. 2 is a simplified schematic block diagram showing an alternative embodiment of a portion of what is shown in FIG. 1.

FIG. 3 is a simplified schematic block diagram showing another alternative embodiment of a portion of what is shown in FIG. 1.

FIG. 4 is a simplified schematic block diagram showing yet another alternative embodiment of a portion of FIG. 1.

FIG. 5 is a simplified schematic block diagram showing still another alternative embodiment of a portion of FIG. 1.

FIG. 6 is a simplified schematic block diagram showing yet another illustrative embodiment of the invention.

FIG. 7 is a simplified schematic block diagram showing still another illustrative embodiment of the invention.

FIG. 8 is a simplified schematic block diagram showing a portion of the FIG. 7 embodiment in more detail.

FIG. 8A is similar to FIG. 8, but shows an alternative embodiment of the type of circuitry that is shown in FIG. 8.

FIG. 9 is a simplified schematic block diagram of illustrative circuitry usable in accordance with the invention.

FIG. 9A is a simplified schematic block diagram showing yet another embodiment of the invention.

FIG. 9B is a simplified schematic block diagram showing still another embodiment of the invention.

FIG. 10 is a more detailed, but still simplified, schematic block diagram of an illustrative embodiment of circuitry usable for a portion of earlier-described embodiments of the invention.

FIG. 11 is a still more detailed, but still simplified, schematic block diagram of an illustrate embodiment of additional possible features of circuitry of the type shown in FIG. 10 in accordance with the invention.

FIG. 12 is a more detailed, but still simplified, schematic block diagram of an illustrative embodiment of circuitry usable for another portion of earlier-described embodiments of the invention.

FIG. 12A is similar to FIG. 12, with the addition of some further optional circuitry in accordance with the invention.

FIG. 13 is a simplified schematic block diagram of further illustrative circuitry usable in accordance with the invention.

FIG. 14 is a simplified schematic block diagram showing an illustrative embodiment of a system including a PLD in accordance with the invention.

FIG. 15 is a simplified schematic block diagram showing an illustrative embodiment of a portion of the FIG. 14 system in more detail.

FIG. 16 is a simplified schematic block diagram showing an illustrative embodiment of another aspect of the invention.

FIG. 17 is a simplified schematic block diagram of an illustrative system employing a PLD in accordance with the invention.

### DETAILED DESCRIPTION

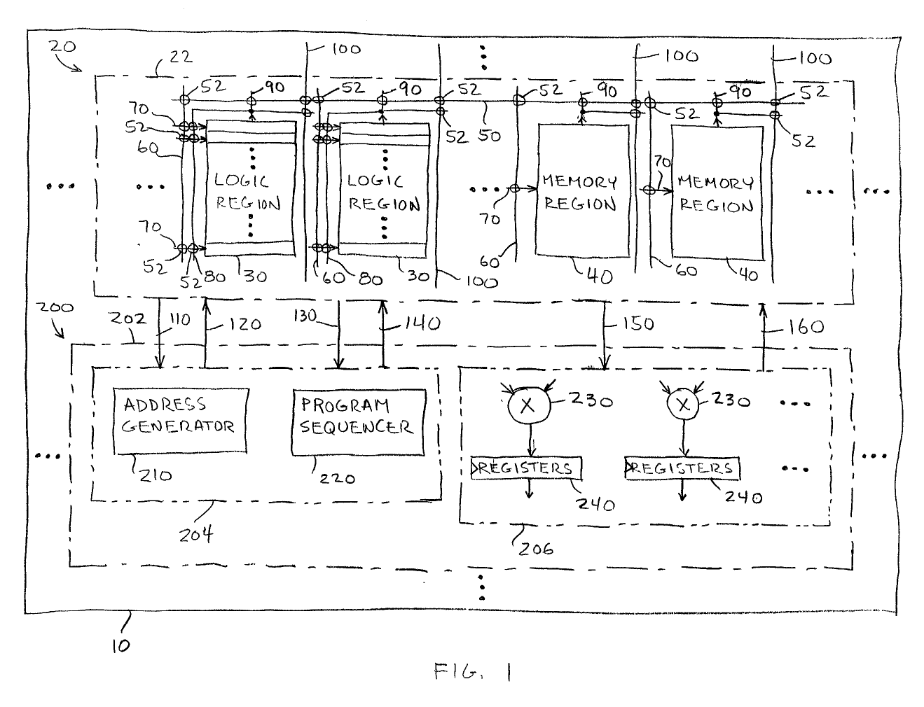

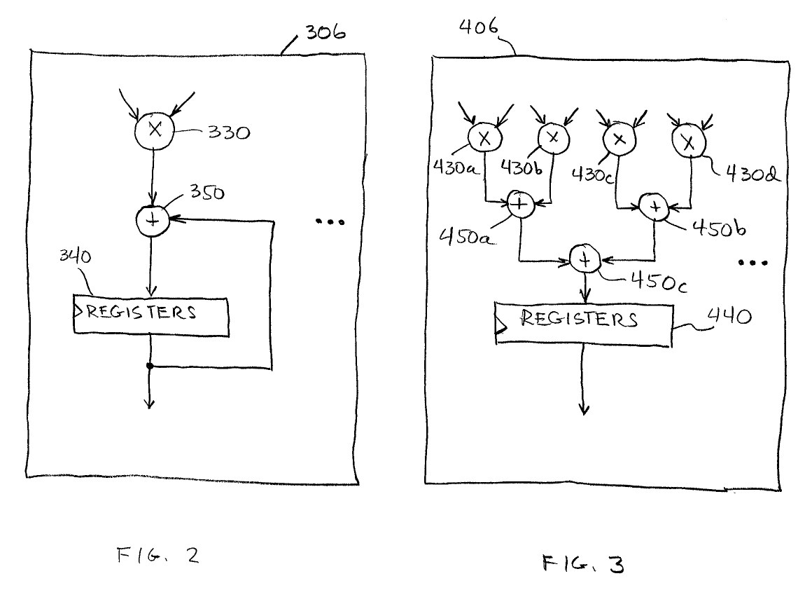

An illustrative PLD 10 constructed in accordance with this invention is shown in FIG. 1. PLD 10 includes a so-called “soft-logic” portion 20 and a so-called “hard-logic” portion 200. Soft-logic portion 20 includes programmable circuitry of the various kinds that it is known (at least in general) to provide on PLDs. Thus, for example, soft-logic portion 20 may include one or more super-regions 22 of programmable logic and memory. Each such super-region 22 may include one or more regions 30 of programmable logic, one or more regions 40 of memory, and local or relatively local interconnection resources. In the particular example shown in FIG. 1 these interconnection resources include super-region-wide interconnection conductors 50 for conveying signals to, from, and/or between regions 30/40 in the super-region; region-feeding conductors 60 for conveying signals from conductors 50 to the vicinity of each region 30/40; input conductors 70 for applying signals from conductors 60 (and any local feedback conductors 80) to the adjacent regions 30/40; output conductors 90 for applying output signals of the regions 30/40 to conductors 50 (and any local feedback conductors 80); and (at least in the case of logic regions 30) local feedback conductors 80. In addition to the above-described local or relatively local interconnection resources, PLD 10 may include more global interconnection resources such as interconnection conductors 100 for conveying signals to, from, and/or between multiple super-regions 22 on the device. The various interconnection resources of PLD 10 also include programmable logic connectors (“PLCs”) 52 (which may include driver circuitry where driving relatively long conductors is required) for selectively interconnecting intersecting ones of the above-mentioned conductors 50/60/70/80/90/100. PLCs 52 may be controlled by programmable function control elements (“FCEs”; not shown separately in FIG. 1) to make or not make the possible connections between intersecting conductors. (The term “PLC” is used herein for a variety of interconnection and/or signal routing resources. It will be understood that PLCs may be either relatively statically controlled (e.g., by FCEs) or more dynamically controlled (e.g., by signals on the PLD that can have different logical values at different times).)

It will be understood that although only single lines are shown for most interconnections herein (and that only single instances are similarly shown for most PLCs), these depictions actually often represent multiple interconnections (and correspondingly multiple PLCs). Thus for example, the single line 50 in FIG. 1 actually typically represents many similar, parallel interconnection conductors. There are also typically many PLCs 52 for selectively connecting those conductors 50 to the many conductors 60 in the group of such conductors represented by each line 60. Later in this specification the same will be true for other groups of multiple connections that are represented only by single lines. Examples are connections 110, 120, 130, 140, 150, and 160 in FIG. 1, the internal connections shown in the operating portion 206 of processor object 202 in FIG. 1, etc.

Hard-logic portion 200 includes one or more processor objects 202, as that term is defined elsewhere in this specification. In the particular example shown in FIG. 1, processor object 202 is adapted to support certain VLIW operations or DSP multiplier-accumulator (“MAC”) operations. Processor object 202 includes control portion 204 and operating portion 206. Both of portions 204 and 206 are hard-wired to at least some extent to enable processor object 202 to more rapidly perform the task or tasks within its capabilities.

As shown in FIG. 1, control portion 204 includes address generator 210 and program sequencer 220. More detail will be provided later regarding illustrative constructions of elements 210 and 220. For the present it will be sufficient to say that address generator 210 may receive certain address and/or control information from soft-logic portion 20 via leads 110, and may output other address information to soft-logic portion 20 via leads 120. For example, address generator 210 may receive from soft-logic portion 20 one or more starting addresses for data to be applied to and processed by operating portion 206. Such addresses may be the addresses of data in memory regions 40, in registers in logic regions 30, or the like. Any such address information may be absolute or relative (i.e., subject to modification by a base offset factor as described later in this specification). Address information output by address generator 210 via leads 120 may be used to actually select the location(s) in soft-logic portion 20 from which data or other information is retrieved for processing by processor object 202. As an alternative or addition to the foregoing, address generator 210 may receive from soft-logic portion 20 one or more starting addresses for the intended destination(s) within soft-logic portion 20 of the data output by processor object 202. Again, any such address information may be absolute or relative. Related address information output by address generator 210 via leads 120 may be used to actually select the locations in soft-logic portion 20 to which the processor object 202 output data will be routed for storage and/or further processing. Depending on the operations performed by processor object 202, the addresses output by address generator 210 may be subject to incrementation or other types of modification (including jumps) in successive cycles of operation of the processor object.

As will become clearer later in this specification, the data address information supplied to address generator 210 as described in the preceding paragraph may come from the address portions of instructions that have been selected for execution by program sequencer 220.

Program sequencer 220 is typically circuitry that is capable of controlling one or more sequences of steps. For example, program sequencer 220 may be capable of selecting a next instruction to be performed by operating portion 206. To do this, program sequencer 220 may receive a starting instruction address and possibly other control information from soft-logic portion 20 via leads 130. As in the case of address generator 210, this address information may be absolute or relative. Program sequencer 220 may automatically increment the starting address during subsequent instruction clock cycles of the apparatus. Instruction addresses output by program sequencer 220 via leads 140 are used to cause desired instructions to be retrieved from memory and executed, typically at least partly by operating portion 206.

As an alternative or addition to such relatively basic operations, program sequencer 220 may be capable—operating relatively independently after being started—of causing or at least keeping track of relatively complex sequences of instruction steps. Such sequences may include repeated performance of instruction loops. Two or more such loops may be “nested” relative to one another. Program sequencer 220 may be capable of handling “interrupts” that, for example, cause one series of operations to be temporarily stopped while another series of operations is performed.

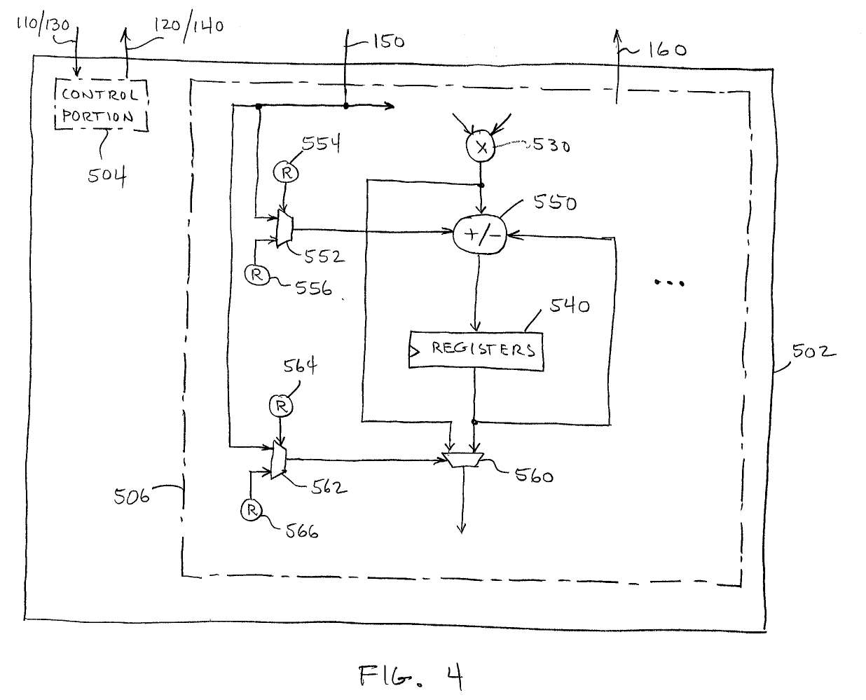

Operating portion 206 is the portion of processor object 202 that actually performs one or more tasks on data supplied to the processor object. This data typically comes from soft-logic portion 20 via leads 150. Any necessary signals for controlling the operation of operating portion 206 may also be supplied via leads 150. The output data of processor object 202 that results from performance of the object's task(s) on the input data is returned to soft-logic portion 20 via leads 160. In the particular example shown in FIG. 1, operating portion 206 has (in parallel with one another) several parallel multipliers 230, each capable of multiplying together two multi-bit input data words (from input leads 150) to produce a multi-bit output product word. Each output word can be temporarily stored in an associated bank of registers 240 (e.g., flip-flops) and then output to soft logic portion 20 via leads 160. (Operating portion 206 is earlier described as including multiplier-accumulator (“MAC”) capabilities. But to avoid over-crowding FIG. 1 and to begin with a simpler example, FIG. 1 only shows operating portion 206 including several separate instances of parallel multipliers 230 with output registers 240. An example of a MAC operating portion is shown in FIG. 2 and described more fully below. Still other examples of operating portion circuitry are shown in FIGS. subsequent to FIG. 2, and also MAC and/or DSP circuitries of the various types shown and described in Langhammer et al. U.S. patent application Ser. No. ______, filed Sep. 18, 2001 (Docket No. 174/199).)

It will be appreciated that dedicated parallel multipliers 230 are a good example of the kind of circuitry that can be advantageously included in an object on a PLD in accordance with this invention. Parallel multiplication is very frequently needed in DSP (e.g., for digital filtering of many kinds). But the general-purpose logic of soft-logic portion 20 may not be particularly efficient for performing parallel multiplication (either with sufficient rapidity or without undue consumption of soft-logic resources). Thus if a PLD is going to have to perform parallel multiplication of relatively long data words at high speed, then equipping the PLD with one or more processor objects that are capable of such operations as shown herein is extremely beneficial.

Processing of instructions for execution by processor object 202 is preferably performed by soft-logic portion 20. Such instructions may take any of many forms. VLIW form is one possible example. The processing of instructions in soft-logic portion 20 may include unpacking, decoding, or the like. Instruction processing may also include using address portions of instructions to select data for processing, and using control portions of instructions to route that data to appropriate portions of the circuitry (e.g., to appropriate portions of operating portion 206) for actual processing. The control portions of instructions may also control selection of selectable aspects of the operations of operating portion 206 and/or routing of data from operating portion 206 back to soft-logic portion 20.

It will be understood that although FIG. 1 shows only one super-region 22 exchanging signals with only one processor object 202, a super-region 22 (or any other quantity of programmable logic) may exchange signals with more than one processor object, and/or a processor object may exchange signals with more than one super-region (or other quantity of programmable logic).

To facilitate rapid communication between soft-logic portion 20 and processor object 202, the various inputs and outputs 110/120/130/140/150/160 of the processor object (especially those for which rapid communication is important) are preferably connected to relatively local interconnection resources in soft-logic portion 20. For example, good candidates for such connections are region-feeding conductors 60, local feedback conductors 80, and region output conductors 90. Preferably these connections can be made relatively short to avoid the need for output drivers between the signal source and the signal destination. Such drivers increase power consumption and add delay to the communication path. Of course, these communication considerations may not be that important in all cases; and if they are not controlling, then other interconnection resources (e.g., conductors 50 and 100) in soft-logic portion 20 may also serve as connection points for any or all of inputs and outputs 110/120/130/140/150/160.

As has already been at least suggested, the particular construction of the operating portion 206 of a processor object shown in FIG. 1 is only one example of many possible constructions. Another example is the illustrative multiplier-accumulator (“MAC”) operating portion 306 shown in FIG. 2. Operating portion 306 includes one or more instances of the following circuitry: dedicated (i.e., at least partially hard-wired) parallel multiplier 330 (similar to an element 230 in FIG. 1), dedicated parallel adder 350 (for adding each successive product word output by multiplier 330 to the current contents of registers 340 to produce a new accumulated value for storage in those registers), and registers 340 (similar to element 240 in FIG. 1).

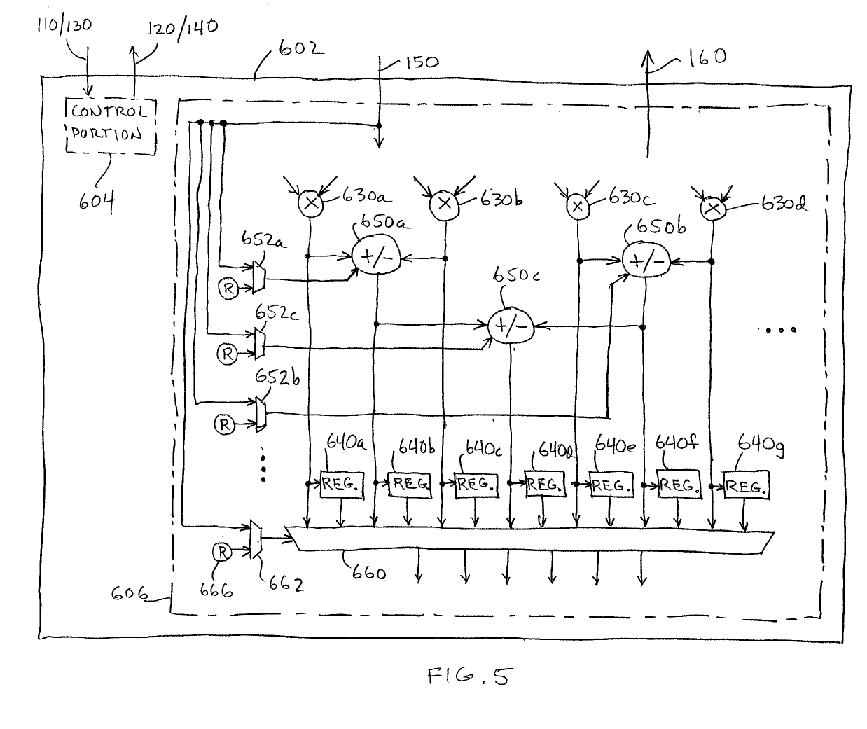

FIG. 3 shows another example of a possible construction of the operating portion of a processor object in accordance with this invention. In FIG. 3 operating portion 406 includes one or more instances of the following circuitry: several dedicated (i.e., at least partly hard-wired) parallel multipliers 430a-d (each of which may be similar to previously described multipliers 230/330), dedicated parallel adders 450a-c (each of which may be similar to previously described adder 350) for collectively adding together the product words output by multipliers 430, and registers 440 (which may be similar to previously described registers 240/340) for registering the parallel outputs of the final adder 450c. The processor object operating portion 406 shown in FIG. 3 has a construction that is particularly suited for performing certain kinds of finite impulse response (“FIR”) digital filtering, which is frequently needed in DSP.

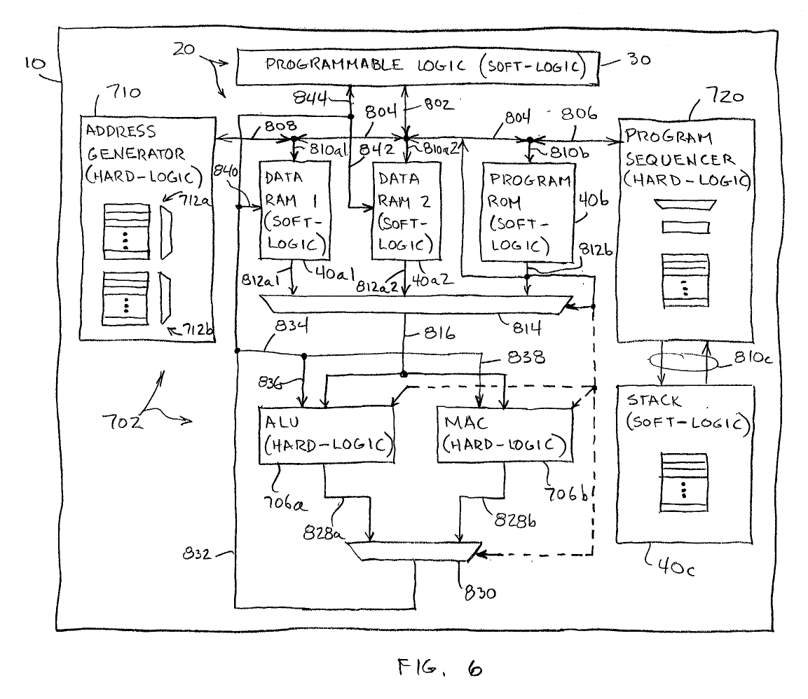

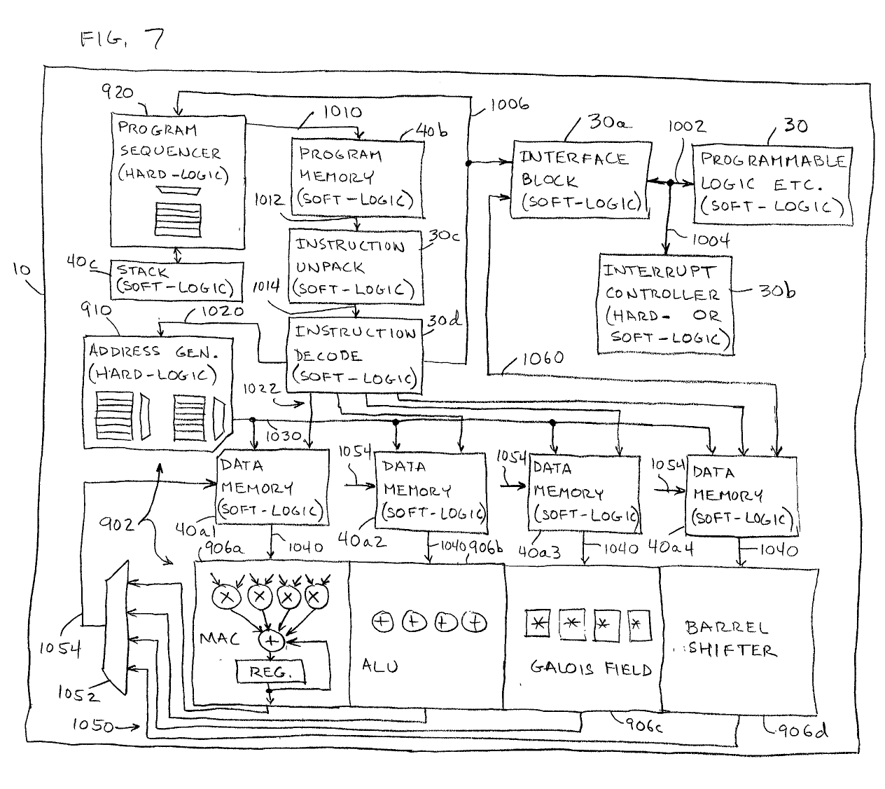

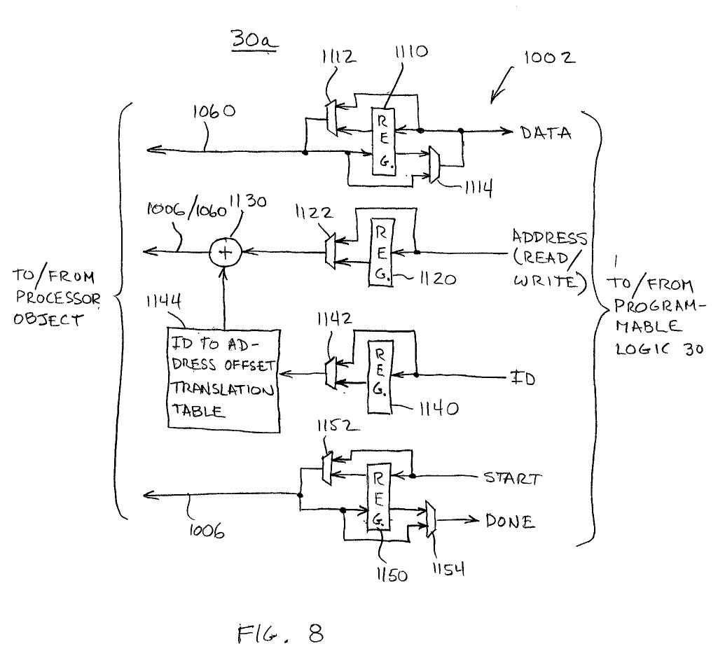

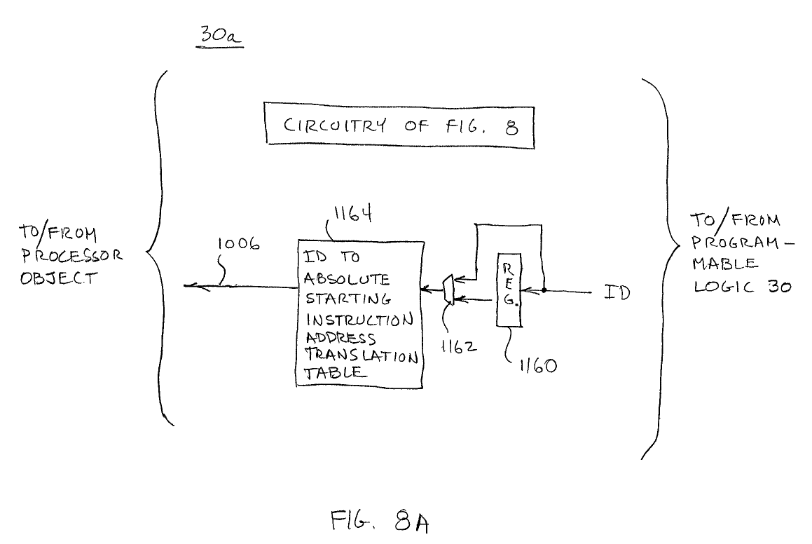

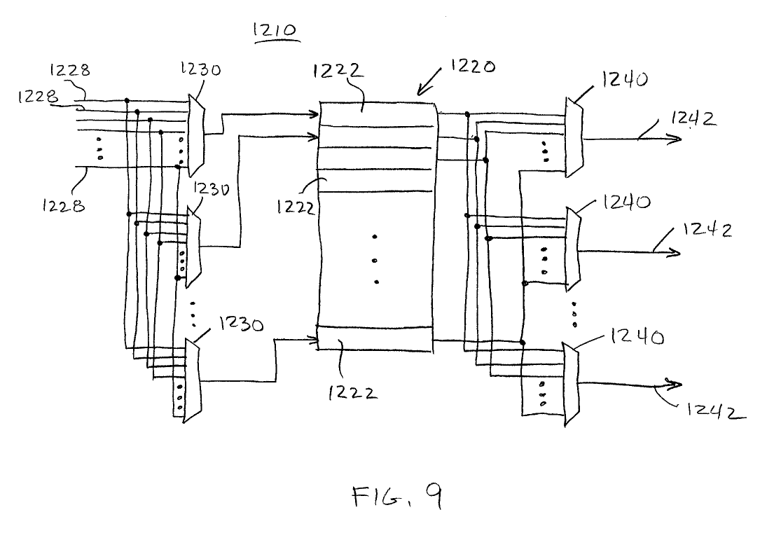

FIG. 4 shows still another example of processor object circuitry in accordance with the invention. In FIG. 4 processor object 502 includes control portion 504 (similar to control portion 204 in FIG. 1) and operating portion 506 (at least conceptually similar to operating portions 206/306/406 in FIGS. 1-3, respectively). FIG. 4 shows some examples of how signals 150 from soft-logic portion 20 may control various aspects of the operation of illustrative operating portion circuitry 506. (The ultimate source of these control signals 150 may be instructions selected for execution by the program sequencer portion of circuitry 504. Of course, the signals on leads 150 may also include data signals).

In FIG. 4 operating portion 506 includes one or more instances of elements 530, 540, 550, 552, 554, 556, 560, 562, 564, and 566. Element 530 is a dedicated parallel multiplier, which may be similar to any of the previously described parallel multipliers such as 230. Element 550 is dedicated parallel adder/subtractor circuitry, which may be generally similar to previously described parallel adder circuitry, but with the further capability that it can alternatively subtract from one another the outputs of multiplier 530 and registers 540. (The output signal of PLC 552 controls whether adder/subtractor 550 adds or subtracts its other inputs. A preferred embodiment of an adder/subtractor is shown in Langhammer et al. U.S. patent application Ser. No. 09/924,354, filed Aug. 7, 2001, although other forms of adder/subtractor circuitry can be used instead, if desired.) Registers 540 may be similar to any previously described registers such as 240. Element 552 is a PLC (in this case, for example, a multiplexer) that is controlled by FCE 554 to select as its output either one of its two other inputs. The two other inputs to PLC 552 are one of signals 150 (in this case a control signal) and the output of FCE 556. Thus FCE 554 can be programmed to control PLC 552 to get its output from either soft-logic portion 20 or FCE 556. If the output of PLC 552 comes from soft-logic portion 20, adder/subtractor 550 can be dynamically controlled (e.g., by an instruction being processed at least in part in the soft-logic portion) to add or subtract at different times during the operation of the PLD that includes object 502. Alternatively, if the output of PLC 552 comes from FCE 556, then adder/subtractor 550 is more statically controlled (by the programmed state of FCE 556) to always add or always subtract.

Element 560 is a PLC (e.g., a bank of parallel multiplexers) for outputting either the parallel outputs of multiplier 530 or the parallel outputs of registers 540, depending on the state of the control signal output by PLC 562. PLC 562 may be similar to PLC 552. It is controlled by FCE 564 to output either the signal on one of leads 150 or the output signal of FCE 566. Thus, if desired, PLC 560 may be dynamically controlled by the just-mentioned lead 150 signal to sometimes output the multiplier 530 outputs and at other times to output the register 540 outputs. Alternatively, PLC 560 may be more statically controlled by FCE 566 to always output the multiplier 530 outputs or the register 540 outputs.

Langhammer et al. U.S. patent application Ser. No. ______, filed Sep. 18, 2001 (Docket No. 174/199) shows a possible alternative construction of circuitry of the general type shown within box 506 in FIG. 4. That alternative construction allows registers like 540 to hold either an accumulated value from adder/subtractor 550 or just the value output by multiplier 530. This obviates the need for PLCs 560, so those PLCs are not strictly necessary.)

FIG. 5 shows yet another illustrative example of a processor object 602 in accordance with the invention. To a large extent FIG. 5 combines features and/or concepts that have already been discussed. Elements that are the same as or similar to previously discussed elements have either the same reference numbers in FIG. 5 or reference numbers that are increased by 100, 200, 300, and/or 400 from reference numbers previously used for the same or similar elements. The discussion of FIG. 5 can therefore be abbreviated and confined to just the significant differences from what has been previously explained.

FIG. 5 shows an operating portion 606 in which more of the adders 650 can alternatively function as subtractors. FIG. 5 also shows an operating portion in which the multiplier/adder tree can be partitioned in any of many different ways, and in which the outputs of any of the various partitions can be output in registered and/or unregistered form. For example, the output of multiplier 630a can be output uncombined with anything else, and that output can be either unregistered or registered by registers 640a (or both the registered and unregistered signals may be output). PLC 660 selects the final outputs of operating portion 606 from among the many registered and unregistered signals applied to that PLC. As another example, adder/subtractor 650a may be used to combine the outputs of multipliers 630a and 630b, and that adder/subtractor output may be output (uncombined with anything else, but either registered, unregistered, or both) by PLC 660. As yet another example, all of adder/subtractors 650 may be used to combine the outputs of all four multipliers 630, and that all-adder/subtractor output may be output by PLC 660 either registered, unregistered, or both. Other examples include outputting some multiplier 630 outputs uncombined, while also outputting combined multiplier outputs. As in FIG. 4, the control of adder/subtractors 650 can be either dynamic (based on inputs 150 from soft-logic portion 20) or static (based on the programmed state of FCEs that supply alternative inputs to PLCs 652a-c). (Not all the FCEs corresponding to those in FIG. 4 are shown in FIG. 5 to avoid overcrowding the drawing.) Also as in FIG. 4, the control of PLC 660 can be either dynamic (based on inputs 150 from soft-logic portion 20) or more static (based on the programmed state of the FCE(s) 666 that supply alternative input(s) to PLC 662).

Still more capability and flexibility may be given to operating portions like 606 in FIG. 5. For example, feedback loops from the outputs of registers 640 to the depicted adder/subtractors 650 or to other adders, subtractors, or adder/subtractors may be provided to allow one or more accumulator functions to be performed, if desired. Use of these feedback loops and accumulator functions may be controlled in generally the same way that the various options actually shown in FIG. 5 can be selected (e.g., by relatively static program control, by dynamic control from soft-logic portion 20, or by programmable selection of either of these types of control). As another example of further capabilities that may be given to operating portion 606 (or any of the earlier-described operating portions), input signal routing somewhat like the operation of PLC 660 may be provided to allow signals applied to various input ports (i.e., groups of leads 150) to be routed to various multiplier 650 inputs. If provided, control of this input signal routing circuitry may be similar to control of PLC 660 (i.e., either static programmed control, more dynamic control from soft-logic portion 20, or either (based on a programmable selection)). As yet another example of additional capabilities that operating portion 606 may have, each n*n multiplier 630 can be selectively split into n/2*n/2 multipliers to operate on multiple half-words. Splitting multipliers into smaller ones is discussed in more detail in Langhammer et al. U.S. patent application Ser. No. ------, filed Sep. 18, 2001 (Docket No. 174/199). Analogous to what is shown and described elsewhere herein (e.g., for the static or dynamic control of adder/subtractors 550 (FIG. 4) or 650 (FIG. 5)), such splitting of multipliers can be controlled or selected either statically or dynamically.

FIG. 6 shows another illustrative embodiment of a PLD 10 that includes a processor object 702 in accordance with this invention. Elements in FIG. 6 that are the same as or similar to previously described elements have the same reference numbers as the corresponding previously described elements (in the case of soft-logic portion elements) or reference numbers in the 700 series and therefore increased by 100, 200, 300, 400, or 500 from the reference numbers used for corresponding elements in earlier FIGS. In the FIG. 6 embodiment processor object 702 includes operating portions 706a and 706b, address generator 710, and program sequencer 720. All of these elements are dedicated to their specific functions (i.e., hard-wired for those functions to at least some extent). For example, operating portion 706a is an at least partly hard-wired arithmetic logic unit (“ALU”) capable of performing any of a wide range of arithmetic and related operations. Similarly, operating portion 706b is an at least partly hard-wired multiplier-accumular (“MAC”) block (e.g., similar to any of the MAC circuitry described earlier in this specification). (As has been mentioned, other examples of possible MAC block circuitry are shown in Langhammer et al. U.S. patent application Ser. No. ______, filed Sep. 18, 2001 (Docket No. 174/199).) Address generator 710 is similar to any of the previously described address generators (e.g., for generating addresses for use in retrieving from the soft-logic portion 20 of PLD 10 data to be operated on by operating portions 706a/706b and/or for use in returning to the soft-logic portion data output by operating portions 706a/706b). Program sequencer 720 is similar to any of the previously described program sequencers (e.g., for generating the addresses in program ROM 40b of successive instructions to be used in controlling at least certain aspects of the operation of operating portions 706a/706b).

The elements in FIG. 6 with reference numbers that are not in the 700 series are preferably elements in the soft-logic portion of PLD 10. These elements include programmable logic 30, data random access memories (“RAMs”) 40a1 and 40a2, program read-only memory (“ROM”) 40b, stack memory 40c, and most or all of the address, data, and control signal buses and associated routing circuitry shown in FIG. 6.

The last-mentioned bus and routing circuitry can be the same as or similar to elements like 50, 52, 60, 70, 80, 90, 100, 110, 120, 130, 140, 150, and 160 in the previously described FIGS. In other words, the bus and routing circuitry in FIG. 6 can be part of the general-purpose, programmable interconnection resources of PLD 10 that can be used either to support the use of processor object 702 or for any other purpose for which those resources are provided. To facilitate depiction and explanation of use of processor object 702, however, these resources tend to be shown in FIG. 6 as though configured (i.e., programmed) to support the use of the processor object. And to avoid unintended specific correlation between particular elements of the interconnection resources as previously depicted and described, completely different reference numbers in the 800 series are used for various portions of the interconnection resources in FIG. 6 and the following discussion of that FIG. Again, however, it will be understood that interconnection resources similar to those described earlier can be used to implement any or all of the interconnection resources (with 800 series reference numbers) in FIG. 6. Also, it will be understood that single lines in the 800 series in FIG. 6 typically represent multiple leads, and that various ones of these leads may convey any or all of “data,” “address,” and/or “control” signals.

Signals for initiating a hard-logic processor object 702 operation can be supplied to program sequencer 720 from programmable logic 30 via leads 802, 804, and 806. By identifying the address of a particular program instruction to be performed, these signals may enable program sequencer 720 to retrieve that instruction (and possibly a succession of other instructions) from program ROM 40b. Each program address output by program sequencer 720 causes program ROM 40b to output a corresponding (i.e., addressed) program instruction via leads 812b. Control and possibly data portions of such an instruction are applied to PLC 814 for any or all of several possible uses. For example, some of the instruction information may be used to control PLC 814 (i.e., the signal routing effected by that PLC). Alternatively, or in addition, some instruction information may be routed through (or around) PLC 814 for use in controlling operating portions 706a and/or 706b and/or the routing effected by PLC 830. Address portions of instruction information output by program ROM 40b may be routed to address generator 710 via leads 804 and 808.

Address generator 710 responds to address information it receives by outputting the address or addresses of data (e.g., data to be processed by operating portions 706a and/or 706b). The address output signals of address generator 710 may be applied to data memories 40a1/40a2 via leads 808, 804, 810a1, and 810a2. Memories 40a1/40a2 respond to these address signals by outputting data from the addressed location(s) via leads 812a1/812a2. PLC 814 routes this data to ALU 706a and/or MAC 706b (e.g., as instructed by the current instruction from program ROM 40b). Leads 816 participate in this routing. ALU 706a and/or MAC 706b operate on this data (and possibly other data as described later). These operations may be partly or wholly controlled by the current instruction from program ROM 40b.

At this point it should be mentioned that the type of address generator 710 described above may be most like a feature commonly associated with DSP processors. Other types of processors may generate their addresses somewhat differently. For example, reduced instruction set computing (“RISC”) processors typically generate their addresses using multiple steps using the program memories and internal logic and registers of the processor. Thus in other embodiments of the invention an address generator 710 may not be necessary or may take a different form than that described herein.

Operating portions 706a and/or 706b output the data signals that result from their operations via leads 828a and 828b, respectively. These signals are applied to PLC 830, which routes the applied signals to appropriate ones of leads 832, 834, 836, 838, 840, 842, and/or 844. As has been mentioned, the routing effected by PLC 830 may be wholly or partly controlled by current instruction information from program ROM 40b. If routed via leads 836 and/or 838, data output by operating portions 706a and/or 706b may go relatively directly back to either or both of those elements for further processing (e.g., with other incoming data from memories 40a1/40a2 in accordance with the same or different program instructions from memory 40b). If routed via leads 840 and/or 842, data output by operating portions 706a and/or 706b may be stored in memories 40a1/40a2 at locations specified by addresses supplied by address generator 710. If routed via leads 844, data output by operating portions 706a and/or 706b may be applied to programmable logic 30 for storage therein and/or for other use therein or thereby. Address information output by address generator 710 may be applied to programmable logic 30 via leads 802 to determine or help determine the ultimate destinations in logic 30 of the data applied via leads 844.

It should be noted here that, although not specifically shown in FIG. 6, data may also flow out of programmable logic 30 to processor object 702 in the same way that data may flow out of memories 40a1/40a2. Address information from address generator 710 (applied via leads 808/804/802) could be used to select or help select the locations in logic 30 of the data to be output to object 702. Routing (not shown) could be provided for conveying data from logic 30 to PLC 814. From that point on use of the data could be as described above for data from other sources such as memories 40a1/40a2.

Address generator 710 is shown in FIG. 6 as including multiple, parallel, address-generating sub-elements 712a and 712b. These multiple sub-elements 712 can be used in any of several different ways. For example, one sub-element 712 can be used to provide addresses for data associated with one of operating portions 706, while the other sub-element 712 is used to provide addresses for data associated with the other of operating portions 706. As another example, one of sub-elements 712 can be used for providing addresses for input data to processor object 702, while the other sub-element 712 is used for providing addresses for output data from processor object 702. Although only two sub-elements 712 are shown in FIG. 6, any number of such parallel sub-elements 712 may be provided in address generator 710.

Like the just-mentioned capabilities of element 710, the capabilities of elements 40b and 720 may be (and indeed preferably are) adequate to support simultaneous, parallel operation of both of operating portions 706a and 706b. Such simultaneous operation may be either independent or wholly or partially linked.

Program sequencer 720 may be able to communicate with a further block of memory 40c via leads 810c for any of several purposes. For example, program sequencer 720 may be able to deal with a succession of interrupts by temporarily unloading its current contents to memory 40c (operating as a push-down/pop-up stack memory). After program sequencer 720 has completed the operations called for by the interrupt, it can reload from memory 40c and resume operations where it left off prior to the interrupt. The circuitry may be equipped to handle any desired depth of multiple, nested interrupts in this way. Use of a dedicated stack 40c is only one of several possible techniques for storing return addresses. As another example, the processor objects of this invention can also or alternatively store stack addresses in data memories 40a1 and/or 40a2.

When program sequencer 720 completes any program sequence, it may signal that it is finished (e.g., by sending a “done” signal to programmable logic 30 via leads 806, 804, and 802).

Again, the embodiment shown in FIG. 6 is only illustrative, and many modifications can be made. For example, processor object 702 may include only one operating portion 706, or it may include more than two operating portions 706. The operating portion(s) 706 provided can be different than the ALU and MAC operating portions shown in FIG. 6. If multiple operating portions 706 are provided, they can be multiple instances of the same circuitry, or they can be wholly or partly of different types. Although PLD 10 in FIG. 6 is shown including only one instance of elements like 710 and 720 with one associated set of operating portions 706, PLD 10 could have multiple instances of all of those elements and therefore multiple processor objects 702. Still further variations and modifications will occur to those skilled in the art.

From the foregoing it will be clear that because of the mix of soft and hard logic in accordance with this invention, a user can configure any given device 10 to include any of a large number of different processors. The user of device 10 is therefore not bound to any particular processor or processor architecture. Instead, the user can use device 10 to effectively “build” any of several different processors or processor types. This invention therefore gives the user the ability to “build” processors out of soft and hard logic in programmable logic.

The further illustrative embodiment shown in FIG. 7 is particularly adapted to handling so-called very long instruction word (“VLIW”) programs (although it can be alternatively used for handling any other type of programs). VLIW programs have instructions that may include relatively long and complex (or at least compound) strings of instruction, address, data, and/or other information. For example, a single VLIW instruction may instruct the apparatus programmed with and therefore controlled by that instruction to perform several operations at least partly in parallel and in one instruction cycle on several different data words to produce several output words. The VLIW instruction may include several instruction portions that respectively identify the several operations to be performed. The instruction may also include several address portions that respectively identify (at least in relative terms) the sources of the input data to be used in the various operations to be performed and the destinations of the output data words produced as a result of those operations.

The embodiment shown in FIG. 7 has some similarities to and commonalities with what has been shown and described in connection with other embodiments. Analogous to the case of FIG. 6, some of the soft-logic portions of the FIG. 7 embodiment that are common to earlier-described elements are identified by the same two-digit reference numbers (possibly with suffixes) that were earlier-used for the same or similar elements. Thus, for example, various portions of what is earlier referred to as programmable logic 30 are identified by reference numbers 30, 30a, 30b, 30c, and 30d in FIG. 7. Similarly, various elements like earlier-described memories 40 are identified by reference numbers 40a1, 40a2, 40a3, 40a4, 40b, and 40c in FIG. 7. On the other hand, most or all of the interconnection circuitry shown in FIG. 7 is preferably implemented by the programmable interconnection resources such as earlier-described elements 50, 52, 60, 70, 80, 90, 100, 110, 120, 130, 140, 150, and 160. In FIG. 7 these interconnection resources are shown as though configured to support processor object 902. It will be understood, however, that because these interconnection resources are largely programmable, they can be alternatively configured in many other ways. To avoid unintended and possibly unduly restrictive correlation between particular interconnection resources in FIG. 7 and particular interconnection resources in other FIGS., completely new reference numbers in the 1000 series are used for all interconnection resources in FIG. 7. In addition, to reduce the length of the following discussion, the phrases “interconnection resource” and “interconnection resources” are shortened to “IR” and “IRs,” respectively. As in previous FIGS., most or all of the IRs shown using single lines in FIG. 7 are actually multiple, parallel signal paths.

The dedicated (i.e., at least partly hard-wired) processor object 902 in PLD 10 in FIG. 7 includes operating portions 906a, 906b, 906c, and 906d, address generator 910, and program sequencer 920. (It could also include other elements such as interrupt controller 30b, but in the particular example shown in FIG. 7 it is assumed that interrupt controller 30b is a portion of the programmable logic of PLD 10.) Several different types of operating portions 906 are shown in FIG. 7. For example, operating portion 906a is shown as a MAC block, operating portion 906b is shown as an ALU, operating portion 906c is shown as Galois Field circuitry (e.g., for performing a specialized type of mathematical operation used in error correction and encryption), and operating portion 906d is shown as a barrel shifter. Any or all of operating portions 906 may be generally similar to previously described operating portions (e.g., operating portions 706 in FIG. 6). Address generator 910 may be similar to any previously described address generator (e.g., 710 in FIG. 6). Program sequencer 920 may be similar to any previously described program sequencer (e.g., 720 in FIG. 6). Program sequencer 920 may work with stack memory 40c in the same way that elements 710 and 40c in FIG. 6 work together. Alternatively, stack addresses can be stored in data memories 40a1 and/or 40a2.

Interface block 30a provides signal transfer and possibly translation between processor object 902 and the elements that support use of that processor object, on the one hand, and the remainder of the programmable logic and other circuitry 30/30b in PLD 10, on the other hand. An illustrative implementation of interface block 30a is shown in more detail in FIG. 8 and described below. For the moment it will suffice to say that interface block 30a may pass data, address, and control information in either or both directions, and in addition it may convert certain relative address information to more absolute address information by making use of address offset information that may be supplied to it. Control-type information is typically passed through interface block 30a between IRs 1002/1004 and IRs 1006. For example, this control information may initiate and subsequently control (e.g., with interrupts) operation of program sequencer 920. Similarly, other such control information (now passed from IRs 1006 to IRs 1002/1004) may indicate that program sequencer has completed a program sequence.

As will become more apparent as the discussion proceeds, an interface block 30a or similar circuitry in accordance with this invention (see also FIGS. 8, 14, and 15) allows access by an external agent to program and data memory based on a function identifier (“ID”). The external agent does not need to know the exact internal memory map of the processor object, but only zero-address based memory maps for each separate function. (The “exact internal memory map of the processor object” is elsewhere herein sometimes referred to as “absolute” addresses, and the “zero-address based memory maps” are elsewhere herein sometimes referred to as “relative” addresses.) The purpose of this is that the external agent(s) can use the processor object as a universal core or resource. In the same manner that discrete, fixed-function cores are commercially available as soft-logic implementations in PLDs, soft cores or resources can now be provided for the types of processor objects on PLDs that are shown and described herein. This goes hand-in-hand with the ability of the processor objects on PLDs of this invention to support multiple functions (not just one), allowing for a size/speed tradeoff. An additional benefit is that developing functions in software is much faster (and easier to fix if bugs are found in the field) than functions in logic. The user does not have to know anything about the memory map (absolute addresses) of the individual functions. A “linker” can assign an ID code to each function active in the processor object and provide a configuration file to initialize translation tables between the zero-address based (relative) addresses used in writing or otherwise creating the functions. In addition, the linker can configure the address translation unit to “protect” application spaces (i.e., only allow a certain range of absolute addresses for each ID). As has been said, the various aspects of this interface-block-type functionality will be explained more fully as the description proceeds.

When operating, program sequencer 920 may output a succession of program instruction addresses appropriate to performing a particular task or several particular tasks. These instruction addresses are applied to program memory 40b via IRs 1010 to cause that memory to output program instructions stored in the addressed locations. As has been mentioned, these instructions may be VLIW instructions.

Each instruction output by memory 40b is applied to instruction unpack block 30c via IRs 1012. Instruction unpack block 30c performs functions such as recognizing that an instruction from program memory 40b is a VLIW instruction that is actually several instructions put together. In such cases, instruction unpack block 30c breaks the VLIW instruction down into separate instructions so that each can be further dealt with more or less separately. As is suggested by its reference number, instruction unpack block 30c is preferably implemented in the programmable logic of PLD 10.

After an instruction has been unpacked by block 30c, it is applied to instruction decode block 30d via IRs 1014. Instruction decode block 30d decodes the instruction information it receives to produce signals for controlling other components such as 40a1-4, 906a-d, and 910 to actually perform the functions specified by the instruction information. Again, as is suggested by its reference number, instruction decode block 30d is preferably implemented in the programmable logic of PLD 10.

VLIW words may be of different lengths, depending on how many operations are to be executed during any given clock cycle. One of the functions of instruction unpack block 30c may be to determine how many separate instructions are in each fetch, and possibly modify the instruction addressing for the following fetches.

As will be apparent from the foregoing, after an instruction has been unpacked (in element 30c) and decoded (in element 30d), it is in a form (output by element 30d via IRs 1020 and 1022) suitable for use in controlling or at least partly controlling address generator 910, memories 40a1-4, and operating portions 906a-d. For example, the unpacked and decoded instruction may provide certain address and/or control information to address generator 910 so that the address generator can output (via IRs 1030) the addresses of data to be retrieved from memories 40a1-4 for use by any or all of operating portions 906a-d. Alternatively or in addition, this address and/or control information may be used by address generator 910 to help it determine and output (via IRs 1030) the addresses in memories 40a1-4 in which data output by operating portions 906a-d will be stored. As still further alternatives or additions to the foregoing, instruction information output by instruction decode 30d via IRs 1022 may be used to address or help address memories 40a1-4 for output of data from those memories and/or for input of data to those memories, and/or such instruction information may be passed on to operation portions 906a-d via IRs 1040 to control or help control the operating portions.

Data output by memories 40a1-4 is applied to operating portions 906a-d via IRs 1040. Operating portions 906a-d perform their function or functions on that data (possibly partly or wholly as determined, controlled, or otherwise influenced by the above-mentioned instruction information from instruction decode 30d). At any given time, any number of operating portions 906a-d may be in use. Although FIG. 7 may suggest that each of operating portions 906a-d can get input data only from a respective one of memories 40a1-4, it will be understood that more data routing flexibility can be provided if desired.

Data output by operating portions 906a-d can be routed back to memories 40a1-4 via IRs 1050, 1052, and 1054. From memories 40a1-4 data can be routed out to the remainder of programmable logic 30 via IRs 1060, interface block 30a, and IRs 1002. (To avoid over-crowding, FIG. 7 only shows such routing 1060 to (and from) memory 40a1-4, but it will be understood that this routing can be duplicated for any or all of the other memories shown.) It will also be appreciated that data can flow in the opposite direction from programmable logic 30 to memories 40a1-4 via elements 1002, 30a, and 1060.

Interrupt controller 30b may be used to respond to conditions that warrant temporarily interrupting a program sequence currently being executed by program sequencer 920. In response to an interrupt command and other interrupt information supplied by interrupt controller 30b to program sequencer 920 via elements 1004, 1002, 30a, and 1006, sequencer 920 may stop its current sequence, store in stack 40c information required to later resume the interrupted sequence, and begin a new (interrupt) sequence. As described earlier for the embodiment shown in FIG. 6, elements 30b, 920, and 40c may be able to support any desired number of nested interrupts. Stack 40c may be alternatively or additionally used to store return addresses other than those of interrupts. Examples are addresses associated with subroutine calls. Also as mentioned previously, processor may alternatively store the stack in other (“main”) memory such as 40a. And the processor may also store much more information than just the return address for a subroutine call.

The instructions for a program (using the term “program ” generically to include any program, subprogram, subroutine, interrupt sequence, etc.) may include an instruction that causes a “done” signal to be generated and sent to other appropriate portions of the circuitry (e.g., from instruction decode 30d via elements 1006, 30a, and 1002 to programmable logic 30) at the completion of the program. Such a “done” signal can be especially useful when the processor object is used as a “universal” core in accordance with certain aspects of the invention. In this type of context the “done” signal lets the external agent know that the processor has completed the current task.

Once again, it will be understood that FIG. 7 is only illustrative of what can be done in accordance with the invention. For example, FIG. 7 does not show every possible interconnection that may be desired. By way of illustration, it may be desirable to use IRs between programmable logic 30 and program memory 40b to load new or modified instructions into that memory. Similarly, the number and types of operating portions 906 shown in FIG. 7 are only illustrative, and other numbers and types of such elements may be used instead if desired. As in the case of the FIG. 6 embodiment, the elements that support use of operating portions 906 preferably have adequate capacity to support parallel operation of as many of portions 906 as are desired. Thus, for example, the length of each VLIW is preferably adequate to control that number of operating portions 906 in parallel, and address generator 910 can preferably generate as many input and/or output data addresses as are required by that number of operating portions 906.

Although it is true that, in general, any interconnection resources on PLD 10 can be used to provide any of the IRs in the 1000 series in FIG. 7 (and other embodiments), it is typically preferable to locate object 902 and the elements that heavily support use of object 902 where relatively local IRs (like elements 60 and 80 in FIG. 1) can be used for most or all of the communication between these components. As has been said, such relatively local IRs tend to be faster, to require less power, to occupy less space, and to have other similar advantages for such extensive interconnections of possibly speed-critical signals.

FIG. 8 shows an illustrative embodiment of interface block 30a (FIG. 7) in more detail. As shown in FIG. 8, interface block 30a includes (from top to bottom as viewed in the FIG.) a data channel, an address channel, an identification (“ID”) channel, and a control channel. As in other FIGS., single interconnection lines and related elements in FIG. 8 represent what are typically multiple interconnections and elements. Thus, for example, the data channel may be 16 conductors wide, and therefore may also include 16 of each of elements 1110, 1112, and 1114.

Considering each of the above-mentioned channels now in more detail, the data channel may include input/output registers 1110 that can be used, if desired, to register data passing through interface block 30a in either direction. The data channel may also include PLCs 1112 for allowing data passing from IRs 1002 to IRs 1060 to bypass registers 1110, if desired. Similarly, the data channel may include PLCs 1114 for allowing data passing from IRs 1060 to IRs 1002 to bypass registers 1110, if desired.

The address channel allows an address (which is at least a relative address) to be applied to the processor object, possibly with modification based on ID information as described below. The incoming address information from programmable logic 30 may be registered by registers 1120, or it may bypass registers 1120 via PLCs 1122. Adder 1130 is provided to allow an address offset value to be added to the outputs of PLCs 1122 if desired.

The ID channel allows programmable logic 30 to supply an ID value that may be unique for each different program that the processor object can perform. This ID value may be registered by registers 1140 or may bypass those registers via PLCs 1142, as desired. The ID value output by PLCs 1142 is applied to table 1144 (e.g., to address a location in table 1144 that contains an address offset value associated with the applied ID value). Table 1144 responds by outputting and applying to adder 1130 the address offset value corresponding to the applied ID value. Adder 1130 adds this offset value to the (relative) address value output by PLCs 1122 to produce a final or absolute address in memory 40 (FIG. 7). This type of “relative” to “absolute” address conversion can be used for either data addresses or for instruction addresses or for both data and instruction addresses. If used for both data and instruction addresses, then two channels (each generally like elements 1120/1122/1130/1140/1142/1144) may be needed so that one channel can be used for data addresses and the other used for instruction addresses. Different offset values may be needed for the data and instruction addresses associated with each ID value. Hence two channels like 1120/1122/1130/1140/1142/1144 may be needed when both data and instruction addresses may need conversion from zero-address based values to absolute address values. It may also be desirable in some cases to provide this type of address conversion capability at other points in the circuitry or information flow in PLDs in accordance with this invention. If that is so, additional instances of interface circuitry like 30a can be provided, or the information needing conversion can be routed through the depicted instance of interface circuitry 30a. Some illustrative examples of this are discussed later in this specification.

The control channel may include input/output registers for registering control signals such as “start” and “done” signals passing in either direction through interface block 30a. Alternatively, registers 1150 may be bypassed in either direction via PLCs 1152 and/or 1154.

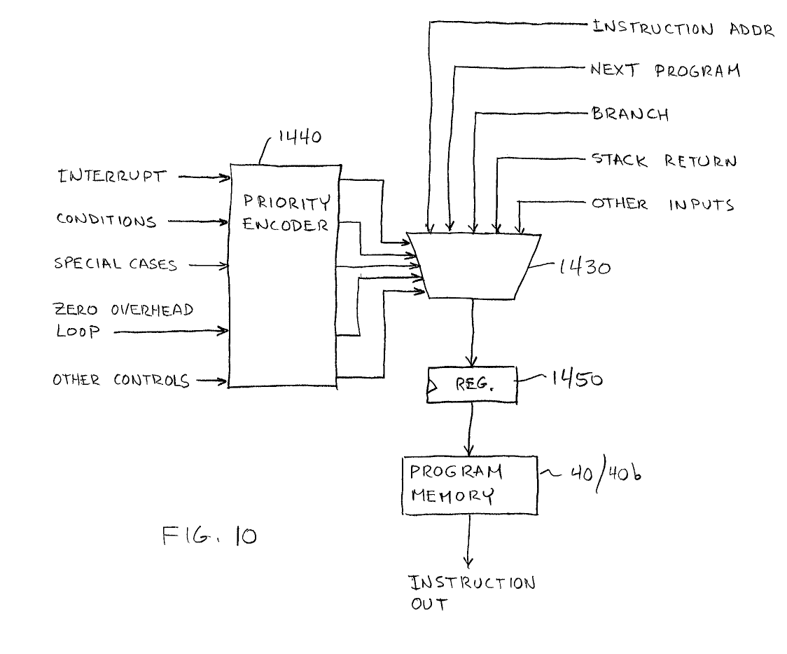

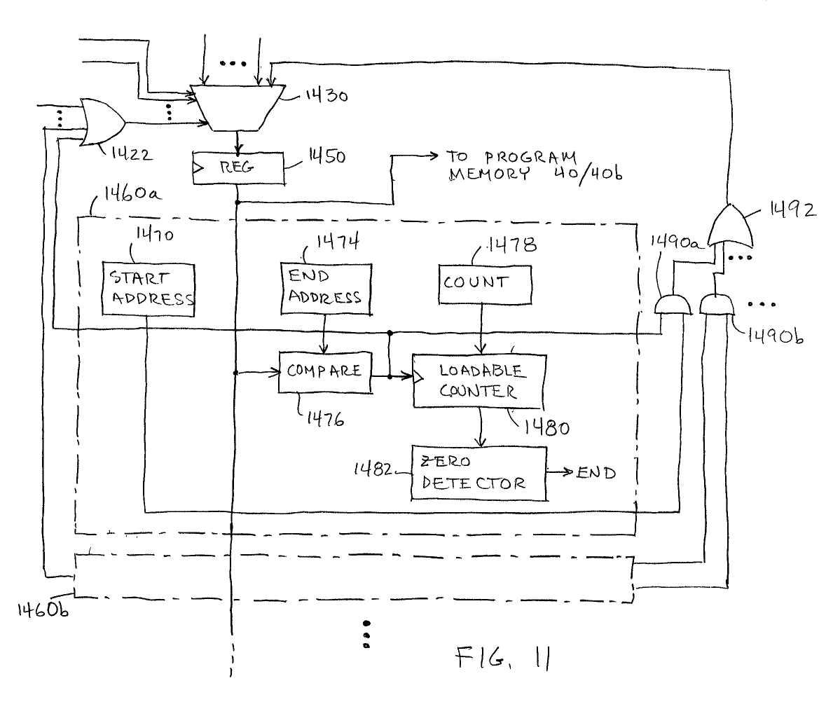

An example of an interface block 30a with both data address offsetting capability and starting instruction address offsetting capability is shown in FIG. 8A. In the FIG. 8A embodiment elements 1120/1122/1130/1140/1142/1144 (FIG. 8) are dedicated to data address offsetting and therefore output to IRs 1060 rather than to IRs 1006. Added elements 1160/1162/1164 are each respectively similar to elements 1140/1142/1144, but are used to convert an ID value for each program to the absolute starting address in memory 40b of the instructions for that program. In addition to outputting a starting address via IRs 1006, circuitry 1164 or associated circuitry outputs via IRs 1006 signals that cause priority encoder 1440 (FIG. 10) to enable PLC 1430 (FIG. 10) to apply that starting address to register or program instruction counter 1450 (FIG. 10). This fetches the first instruction from memory 40/40b. Thereafter, register 1450 increments in successive instruction clock cycles to fetch successive instructions of the relevant program from memory 40/40b. (Other aspects of FIG. 10 are discussed in more detail below.)

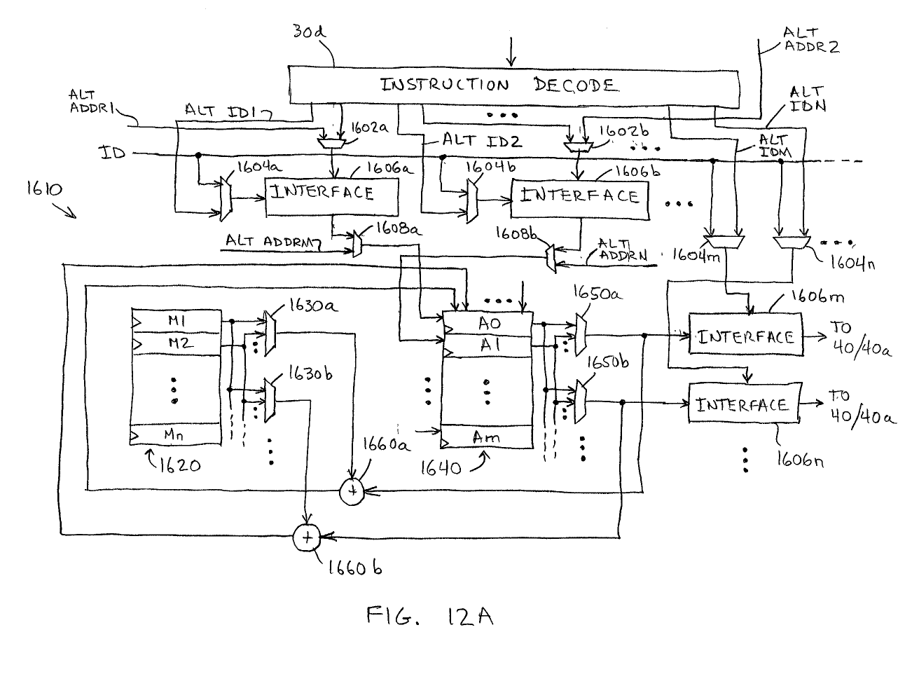

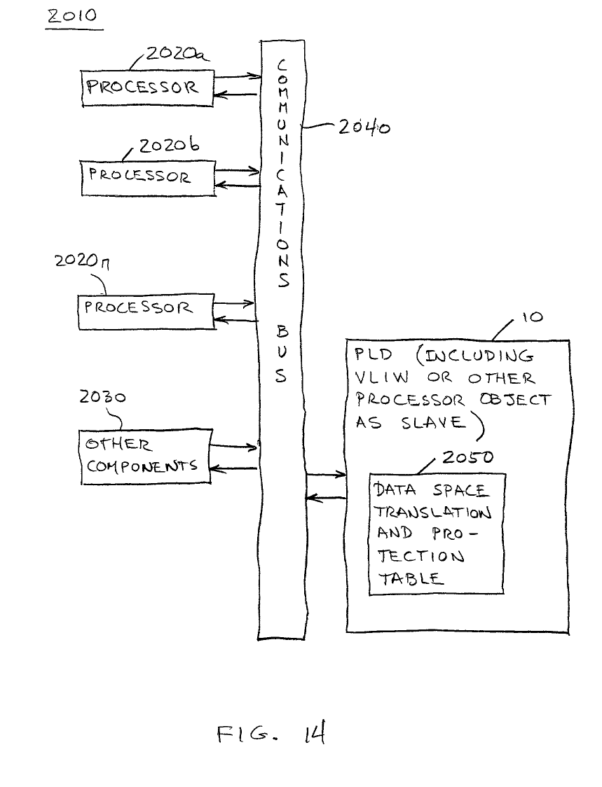

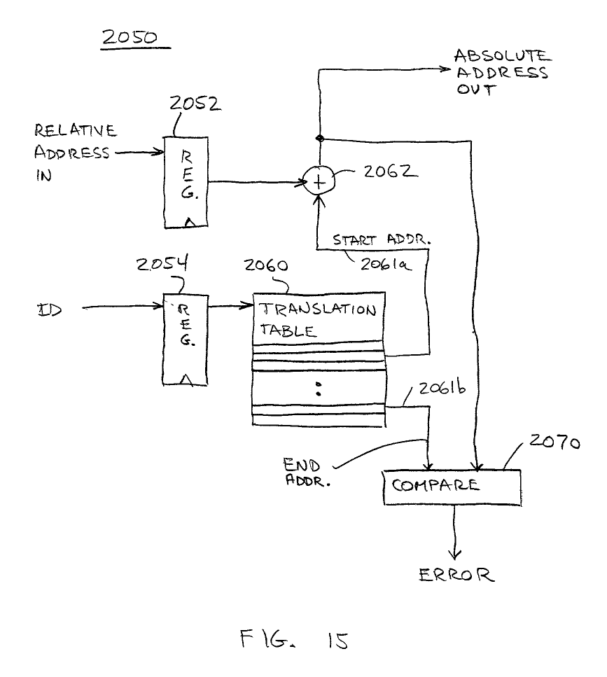

Interface blocks 30a of the types shown in FIGS. 8 and 8A have the advantage that they allow the commands for each program to be written in abstract terms using the same relative data and/or instruction addresses as may be used in other programs. For example, the relative instruction addresses for each program may begin with zero. When the programs are actually loaded in PLD 10 (e.g., in separate portions of program memory 40b in FIG. 7), the amount of offset from absolute program memory location zero for each program's instructions becomes the offset value stored in table 1144 (FIG. 8) or table 1164 (FIG. 8A) for that program. When each program is called, the ID value associated with that program is used to retrieve from table 1144 or 1164 the appropriate address offset value for that program. In the case of FIG. 8, adder 1130 adds that offset value to the relative instruction addresses provided for that program via elements 1120/1122. In the case of FIG. 8A, the output of table 1164 is directly usable as the absolute instruction address. This approach greatly simplifies the writing and debugging of programs for PLDs with processor objects as described herein. A similar approach can be used for data addressing (e.g., the addresses that may be used for data within instructions) (see also, for example, the discussion of FIGS. 12 and 12A below). Use of relative-to-absolute address conversion for data addressing still further facilitates the writing and debugging of programs for PLDs with processor objects. Also, later in this specification, it will be explained how these concepts can be extended to larger systems including PLDs in accordance with this invention (see, for example, the discussion of FIGS. 14 and 15). It should also be understood that additional interface features described in connection with FIGS. 14 and 15 can also be included in or added to circuitry of the types shown in FIGS. 8 and 8A.

Although the illustrative interface blocks 30a shown in FIGS. 8 and 8A are referenced to the particular PLD embodiment shown in FIG. 7, it will be understood that this type of interface can be used with any embodiment of the invention.

From the foregoing it will now be better appreciated that the PLDs of this invention have a number of advantages. If enough of the appropriate kinds of processor objects (with enough of the appropriate kinds of operating portions) are provided on the PLD, the user can use the PLD to implement a custom processor. Such a custom processor can, for example, have the features of a conventional microprocessor, but it can also have added features. For example, it can have more parallel functional units (operating portions) than a conventional microprocessor. The PLDs of this invention can be “cheaper” overall than PLDs with full, dedicated microprocessors on board because, for example, if a user does not need a full microprocessor, it is not there with all of its expensive overhead circuitry. With the present invention the user has access to each processor building block, and the user can therefore use those building blocks in other applications if they are not needed to implement a full microprocessor. For example, a MAC block can be used as part of a DSP processor, or it can be alternatively used for other dedicated data path operations. As another example, a program sequencer can be alternatively used as a complex state machine.

The dedicated circuitry (including processor objects) provided on PLDs in accordance with this invention is preferably adapted to perform what would be the slowest and/or least efficient portions of microprocessor operations if performed in the programmable logic 30 of the PLD.

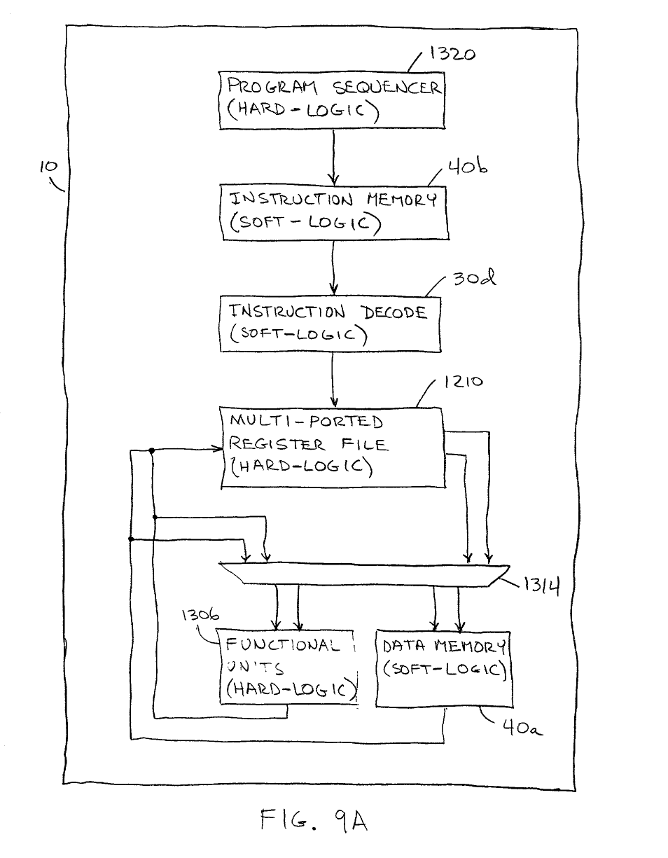

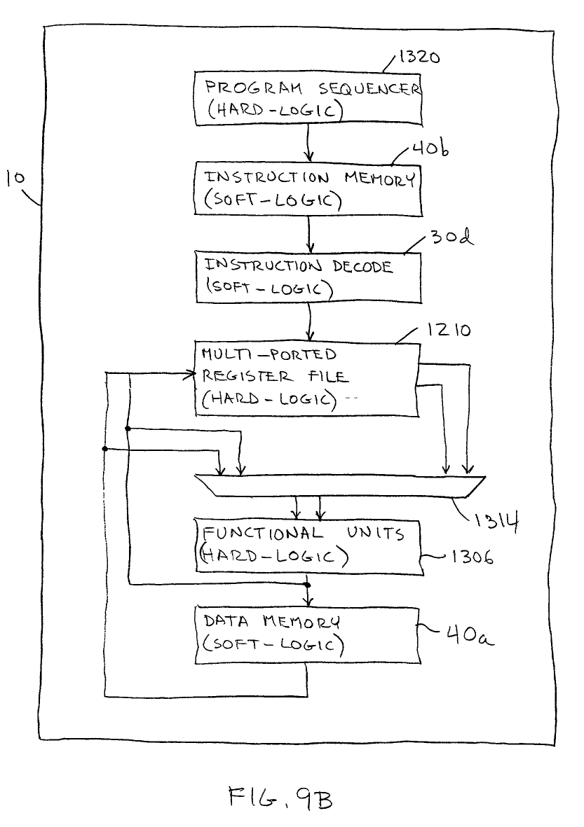

Another example of control circuitry that it may be advantageous to include in the hard-logic processor object portion of PLDs in accordance with this invention is a multi-ported register file, e.g., of the kind shown in FIG. 9. A register file is a control unit (e.g., like a program sequencer or an address generator). A register file may be used as a local storage between the main memories and the functional units. Reduced instruction set (“RISC”) processors generally do not have address generators, the addresses being calculated and stored along with local storage in a register file.

As shown in FIG. 9, a multi-ported register file 1210 includes a memory 1220 including several (e.g., 16) registers 1222, each of which is capable of storing a multi-bit (e.g., a 16-bit) data word. Each register 1222 has an associated input PLC 1230 and an associated output PLC 1240. Each input PLC 1230 is capable of applying any one of eight, 16-bit input words to the associated register 1222 for storage in that register. The eight 16-bit inputs 1228 to register file 1210 are sometimes referred to as the input ports of the register file. Each output PLC 1240 is capable of applying the contents of any one of the 16 registers 1222 to an associated output port 1242 of the register file. Each of PLCs 1230 and 1240 may be either programmably controlled (e.g., by FCEs) to make a basically fixed selection, or more dynamically controlled (e.g., by time-varying logic or other control signals) to make a more dynamic selection. All of PLCs 1230 and 1240 are operable in parallel so that as many as eight input words can be routed into register file 1210 simultaneously and at the same time that as many as eight output words are being routed out of the register file. The circuitry is completely flexible and non-blocking, allowing an input word from any input port 1228 to be applied (after a minimum delay of one clock cycle for operation of registers 1222) to any one or more of output ports 1242.

A register file of the type shown in FIG. 9 can be relatively expensive to implement in the general-purpose programmable logic 30 of a PLD 10 as shown and described herein, but it is easily implemented in dedicated (e.g., hard-wired or partly hard-wired) circuitry. Accordingly, register file 1210 is another example of a good candidate for inclusion in the control portion (e.g., 204/504/604/etc.) of a processor object on a PLD in accordance with this invention. In certain architectures a register file can be used as an address generator (e.g., as address generator 910 in FIG. 7).

It will be understood that the specific sizes mentioned above for various aspects of register file 1210 are only illustrative, and that other sizes can be used instead if desired. For example, the register file can have more or less than the 16 registers 1222 mentioned above, and the size of each register can be smaller or larger than the 16 bits mentioned above. Similarly, the register file can have more or less than the eight input ports and eight output ports mentioned above. The number of inputs and outputs in the register file can be different.

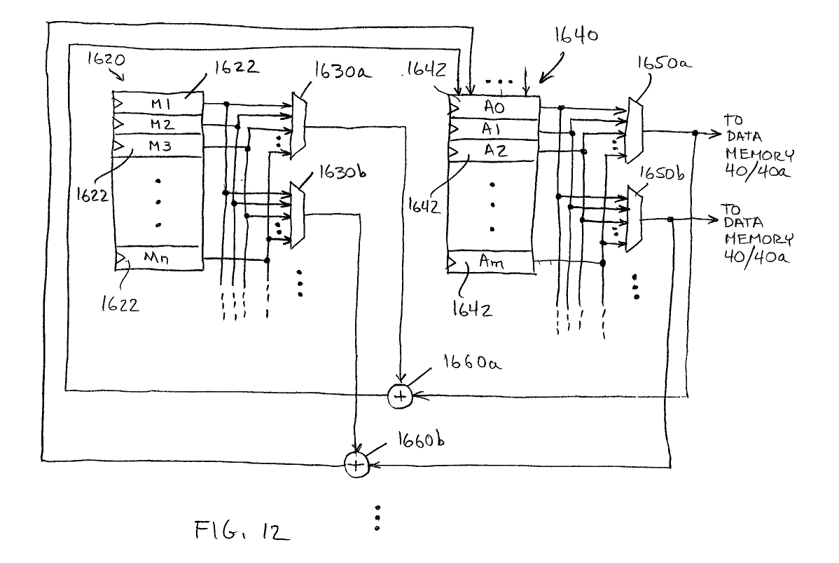

FIG. 9A shows an illustrative PLD 10 in accordance with this invention that includes and makes use of a multi-ported register file 1210 as described above. The architecture shown in FIG. 9A is an architecture that can be used to implement a RISC processor. In addition to the elements shown in FIG. 9A, PLD 10 may also include other soft-logic elements and other hard-logic elements. Program sequencer 1320 may be like the program sequencers described elsewhere in this specification, although in a RISC processor the program sequencer usually does not have zero overhead looping as described later in connection with FIGS. 10 and 11. Each block 40b, 30d, etc., connected by an arrow in the vertical, can be a pipeline stage, but does not have to be such a stage. The multiplexer 1314 between register file 1210, on the one hand, and functional units 1306 and data memory 40a, on the other hand, can also accept calculations in progress without having to write them back into the register file first. This is known to those skilled in the art as “forwarding.” Register file 1210 has at least one input port and two output ports. Functional units 1306 comprise one or more of what are earlier described in this specification as operating portions (e.g., like 206 (FIG. 1), 306 (FIG. 2), 406 (FIG. 3), 506 (FIG. 4), 606 (FIG. 5), 706 (FIG. 6), 906 (FIG. 7), etc.).

An alternative RISC architecture is shown in FIG. 9B. This architecture is similar to FIG. 9A, but in this case data memory 40a is in line with functional units 1306.

An illustrative embodiment of a program sequencer usable in any of the embodiments of this invention is shown in more detail in FIG. 10. For ease of reference, the program sequencer shown in FIG. 10 is referred to as program sequencer 1420, but it will be understood that it can be used for any of the program sequencers (e.g., 220, 520, 620, etc.) mentioned above.

Program sequencer 1420 includes PLC 1430 (basically multiplexer-type circuitry) for selecting any of its several inputs (“instruction address”, “next program”, “branch”, “stack return”, “other inputs”) as the source of instruction address signals output by that PLC. PLC 1430 is controlled to make its selections by several control input signals (“interrupt”, “conditions”, “special cases”, “zero overhead loop”, “other controls”). These signals may be preprocessed by (optional) priority encoder circuitry 1440. For example, encoder circuitry 1440 may make sure that mutually inconsistent control signals are not being asserted; or that if such signals are being asserted, then only the control signals with the highest priority are output for use in controlling PLC 1430. Program sequencer 1420 may further include (optional) register 1450 for registering the instruction address signals output by PLC 1430. (The elements including register 1450 may include circuitry for normally incrementally modifying (e.g., incrementing) the contents of register 1450 during each successive instruction cycle, unless that normal mode of operation is over-ridden by some different output from PLC 1430. Thus register 1450 may also be thought of as a program instruction counter.) As is described earlier, program memory 40/40b is typically not part of the dedicated (i.e., at least partly hard-wired) program sequencer circuitry 1420, but it is shown in FIG. 10 for completeness. Program memory 40/40b is addressed by the output signals of elements 1430/1450 and outputs the program instruction to be executed from the addressed location in that memory.

Many of the various types of input signals shown in FIG. 10 have already been discussed in other contexts, so it will only be necessary to briefly touch on them again here. The “instruction address”, “next program”, “branch”, and “other inputs” signals typically originate in the soft-logic portion 20 (e.g., FIG. 1) of the PLD 10 that includes program sequencer 1420. Some or all of these signals may have passed through interface circuitry 30a like that shown in FIGS. 8 and 8A, and so some or all of these signals may have been subject to interface circuitry processing (e.g., modification of relative addresses with offset values or ID to absolute starting address conversion) as described above. Certain of the “other inputs” signals may be used to support “zero overhead loop” capabilities of the program sequencer as discussed in more detail below in connection with FIG. 11. In that case those “other inputs” signals may be generated more locally to (e.g., within) the program sequencer. The “stack return” input signals may specifically came from the stack memory 40c (e.g., FIG. 7) used with the program sequencer (which stack memory is also typically part of the soft-logic portion 20 of the PLD). The “interrupt”, “conditions”, “special cases”, and “other controls” signals may also originate in the soft-logic portion 20 of the PLD 10 that includes program sequencer 1420. Again, some or all of these control signals may pass through interface circuitry 30a like that shown in FIGS. 8 and 8A. The “zero overhead loop” signals may also originate in the soft-logic portion 20 of the PLD, or they may be generated more locally within program sequencer 1420, assuming that the program sequencer has the capability to generate such signals.

The “zero overhead loop” condition refers to a program sequencer 1420 that can by itself perform such functions as controlling the repeated performance of groups of instructions. For example, a program sequencer in accordance with this invention may be able to use an externally applied instruction address as a starting address for a sequence of instructions that the program sequencer performs repeatedly without further external instructions. When this type of operation is desired, the “zero overhead loop” control signals are asserted (e.g., by the soft-logic portion 20 of the PLD or by program sequencer 1420 itself), and PLC 1430 outputs instruction addresses from the “other inputs” signals. These “other inputs ” signals are starting instruction address signals generated by program sequencer 1420 itself. Illustrative program sequencer circuitry with “zero overhead loop” capabilities is shown and described in more detail later in this specification (e.g., in connection with FIG. 11).

It is advantageous to provide the program sequencer such as 1420 as part of the hard-logic portion(s) (e.g., 200 in FIG. 1) of PLDs in accordance with this invention for reasons such as the following. Some of the inputs to the program sequencer may be the result of relatively deep decodes and other relatively time-consuming operations within the soft-logic portion 20 of the PLD. By the time (during a PLD clock cycle) that the program sequencer receives all of its inputs, there may not be very much time remaining in the clock cycle for the program sequencer to perform its operations. It is therefore advantageous to use dedicated circuitry for the program sequencer to speed up its operations so that it can be made to complete its operations in only a relatively small fraction of a PLD clock cycle.

FIG. 11 shows in more detail how program sequencer 1420 can be provided with illustrative “zero overhead loop” capabilities. In the illustrative embodiment shown in FIG. 11, program sequencer 1420 includes at least one instance (and possibly multiple instances) of loop control circuitry 1460. The following discussion is for representative loop control circuit 1460a, but it will be understood that everything said is equally applicable to any other instances 1460b, etc., of such circuitry.

Loop control circuit 1460a includes start address register 1470, end address register 1474, and count register 1478. Start address register contains the address of the instruction in program memory 40/40b that begins the loop controlled by circuit 1460a. End address register 1474 contains the address of the instruction in program memory 40/40b that ends the loop controlled by circuit 1460a. Count register 1478 contains the number of times the loop controlled by circuit 1460a is to be performed. Registers 1470, 1474, and 1478 may be loaded with the above-described information in any of several ways. For example, these registers may be loaded when the PLD 10 in which they are included is initially configured (programmed). Thereafter, these registers may be used as ROM. Alternatively, one or more of these registers may be loaded from the soft-logic portion (e.g., 20 in FIG. 1) of the PLD. As just one example of how this may be done, an instruction from program memory 40/40b may be used to load some or all of these registers. Such an instruction from memory 40/40b might have an interpretation like the following: “Load circuit 1460a with start address 1050, end address 1056, and count 8,” where the underlined items are preferably variable fields within such an instruction.

Circuit 1460a also includes compare circuit 1476, resettable and loadable counter 1480, and zero detector circuit 1482. Counter 1480 is selectively resettable and loadable with the count value contained in register 1478.

When it is desired to begin performance of a zero overhead loop, the above-described instruction which sets up the registers 1470/1474/1478 for that loop (or some other instruction) may cause register 1450 to receive the start address for that loop and may also cause counter 1480 to load the count value from register 1478. Register 1450 then increments through the first performance of the loop until register 1450 reaches the address of the final instruction of the loop. When that happens, compare circuit 1476 detects that the contents of register 1450 equal the contents of end address register 1474. Compare circuit 1476 then produces an output signal that decrements counter 1480, enables OR gate 1422 (thereby enabling PLC 1430 to pass the output signals of OR circuitry 1492), and enables AND circuitry 1490a. When thus enabled, AND circuitry 1490a applies the start address from register 1470 to PLC 1430 via OR circuitry 1492. This causes register 1450 to again receive the start address of the loop so that performance of the loop begins again.

The loop continues to be performed repeatedly as described above until counter 1480 has counted down to zero. This is detected by zero detector circuitry 1482, which produces an “end” output signal for preventing further performance of the loop. For example, the “end” output signal may zero registers 1470/1474/1478, or the “end” output signal may disable the AND circuitry 1490a associated with that “end” signal.

If (as shown in FIG. 11) program sequencer 1420 includes multiple instances of loop control circuitry 1460, these multiple instances may be used in nested relationships to one another. In such a case, the loop performed by one instance 1460x may include an instruction to initiate performance of the loop controlled by another instance 1460y. Each time instance 1460x calls this instruction, operation of instance 1460x will be temporarily stopped (e.g., by the just-mentioned instruction), and instance 1460y will be enabled to begin performance of the loop it controls. When the use of instance 1460y is finished, instance 1460x can resume its operations. Any desired depth of such nesting can be allowed.

Those skilled in the art will recognize that efficient loop capability of the type described in connection with FIG. 11 can be very helpful in many applications such as DSP applications. Accordingly, providing PLDs with this kind of capability in accordance with this invention greatly facilitates use of such PLDs in DSP and other generally similar applications. Those skilled in the art will also appreciate that the particular loop control circuitry shown in FIG. 11 is only illustrative, and that variations of such circuitry can be used instead if desired. For example, rather than supporting multiple performance of a series of instructions (i.e., looping), such circuitry may only support a single pass through a series of instructions. Another form of zero overhead loop (which requires less hardware to support than the general case in the drawings) is a “Repeat” instruction, which runs a single instruction a number of times.

An illustrative embodiment of address generator circuitry 1610—that can be used for any of the previously described dedicated address generators 210, 510, 610, etc. —is shown in more detail in FIG. 12. Address generator 1610 includes a memory 1620 having a plurality of registers 1622 for storing a plurality of address modifier data words Ml-Mn. The contents of each of registers 1622 are applied to at least one (and preferably a plurality) of PLCs 1630a, 1630b, etc. Each PLC 1630 is controllable to output any one of the register contents applied to it. The register 1622 contents output by each of PLCs 1630 are applied to a respective one of adders 1660.

Address generator 1610 also includes another memory 1640 having a plurality of registers 1642 for storing a plurality of address words AO-Am. The contents of each of registers 1642 are applied to at least one (and possibly a plurality) of PLCs 1650a, 1650b, etc. Each PLC 1650 is controllable to output any one of the register contents applied to it. The register 1642 contents output by each of PLCs 1650 are applied to a respective one of adders 1660. These PLC 1650 output signals are also output by address generator 1610 and are therefore available elsewhere on the PLD 10 (e.g., FIG. 1) that includes the address generator. For example, these address signals may be used for addressing data memories 40/40a on the PLD as described earlier in this specification.

Each of adders 1660 adds the values represented by the signals applied to it. Thus adder 1660a, for example, adds to the address value output by PLC 1650a the address modifier value output by PLC 1630a to produce a modified address value. (The modified address value can, of course, be the same as the original address value if the associated address modifier value is zero.) Each modified address value is routed back to and stored in the original address register 1642 in response to the next instruction clock signal pulse. Thus the address values in memory 1640 can, if desired, be repeatedly incremented, decremented, or otherwise increased, decreased, or modified during successive instruction clock signals. This arrangement of address feedback through adders 1660 facilitates use of address generator 1610 to automatically address data memory locations that it will be necessary to successively address in the course of performing a succession of operations in the PLD.

Memories 1620 and/or 1640 can receive address and/or modifier data in any of several ways. For example, these memories can be partly or wholly loaded with data as part of the configuration (programming) of the PLD 10 (e.g., FIG. 1) that includes address generator 1610. Alternatively or in addition, memories 1620 and/or 1640 can be loaded or can receive new or modified data from the soft-logic portion 20 (e.g., FIG. 1) of the PLD at any time during post-configuration operation of the PLD. For example, an instruction selected from program memory 40/40b by program sequencer (e.g., 220 in FIG. 1) may cause new or modified data to be loaded into specified locations in either or both of memories 1620 and 1640.

As shown in FIG. 12, address generator 1610 is preferably constructed so that it can output two or more addresses simultaneously and in parallel with one another. Such capability is helpful in many contexts such as DSP, wherein it is frequently necessary to arithmetically or otherwise logically combine two or more data words (e.g., by multiplying one data word by another (scale factor) data word). VLIW processing may be facilitated by having address generator 1610 able to output significantly more than two addresses because VLIW instructions often require the processing of quite a few different data words. Address generator 1610 may not only be used to generate the addresses of data words to be retrieved from memories 40/40a or elsewhere, but also to generate the addresses of locations to which data words that result from operations currently being performed should be sent (e.g., for storage). This is another reason why it may be advantageous for address generator 1610 to be able to simultaneously output multiple addresses (i.e., one or more for data to be retrieved, and one or more for the destination(s) of data generated.) If desired, address information applied to, retrieved from, and/or handled within address generator 1610 can be subject to the kind of “interface” processing that is illustrated, for example, by FIGS. 8 and 8A (especially elements 1130 and 1144 in FIG. 8). In other words, circuitry like elements 1130 and 1144 may be included at any appropriate point or points within or associated with address generator 1610 to convert address information from relative to absolute address values. For example, address information supplied to memories 1620 and/or 1640 may be passed through an arrangement of elements like the arrangement of elements in FIG. 8 to convert that information from relative values that can be reused for different operations to absolute values that are unique for each operation, with each operation having its own unique “ID” value for use in controlling the conversion. As another example, a similar approach can be applied to the outputs of PLCs 1650 (beyond the feedback loops back to adders 1660) so that address generator 1610 works internally with relative address information, but the circuitry outside the address generator receives absolute address information.

FIG. 12A shows some illustrative examples of how the circuitry of or associated with illustrative address generator 1610 may be augmented with “interface” circuitry of the type described in the immediately preceding paragraph. Instruction decode 30d (as in FIG. 7) may output instruction and data address information from each of several parts of a VLIW instruction. The instruction information output from each such part of a VLIW instruction may include “ID” information (“ALT ID1” , “ALT ID2”, “ALT IDN”, etc.). This ID information is applied to a respective one of PLCs 1604a, 1604b, 1604n, etc. Another input to each of these PLCs may be a common ID signal “ID”. Each PLC 1604 is controllable (e.g., programmable) to select either the associated specific ID signal or the common ID signal for application to the associated interface circuitry 1606a, 1606b, 1606n, etc.

Each of interface circuits 1606 may be like elements 1130 and 1144 in FIG. 8. Thus each interface circuit 1606 responds to its ID input signal (from the associated PLC 1604) by selecting a corresponding previously stored data address offset value for addition to a relative data address value also applied to the interface circuit.

Returning to instruction decode 30d, the data address information output from each part of a VLIW instruction may be a relative data address and is applied to a respective one of PLCs 1602a, 1602b, etc. Each of PLCs 1602 may also receive other relative data address information (“ALT ADDR1”, “ALT ADDR2”, etc.) from other sources (e.g., from other parts of the soft-logic portion of PLD 10). Each of PLCs 1602 is controllable (e.g., programmable) to select either of its data address inputs for outputting to the associated interface circuitry 1606a, 1606b, etc. (this paragraph does not apply to PLCs 1606m, 1606n, etc.). Each interface circuit 1606a, 1606b, etc. converts the relative data address information it receives to absolute data address information and applies that information to the associated PLC 1608a, 1608b, etc. Each PLC 1608 may also receive other address information (“ALT ADDRM”, “ALT ADDRN”, etc.) from other sources (e.g., from other parts of the soft-logic portion of PLD 10). Each of PLCs 1608 is controllable (e.g., programmable) to select either of its data address inputs for outputting to an associated one of the registers in memory 1640, e.g., to load a data address into that register.

Turning now to interface circuits 1606m, 1606n, etc., each of these circuits receives the data address information output by an associated one of PLCs 1650a, 1650b, etc. Accordingly, each of circuits 1606m, 1606n, etc., can convert relative data address information applied to it from the associated PLC 1650 to absolute data address information (for use in addressing memories 40/40a (e.g., FIG. 7)) based on the ID information also applied to that interface circuit from the associated PLC 1604.

It will be understood that it is unlikely for all of the interface circuitry shown in FIG. 12A to be used in any one configuration of PLD 10. For example, if interface circuitry 1606a is being used to convert relative data address information to absolute data address information for register A0 in memory 1640, it is unlikely that the output of that register will need further conversion by any of interface circuits 1606m, 1606n, etc. Similarly, if one of downstream interface circuits 1606m, 1606n, etc., is being used to convert certain outputs of memory 1640, it is unlikely that additional upstream conversion (by interface circuits 1606a, 1606b, etc. (but not including 1606m/1606n/etc.))will be needed in that particular information pathway. The illustrative configuration shown in FIG. 12A is designed to provide many different possible configurations of use, including uses such as the following (considering just one representative data address pathway through the circuitry):

1. relative or absolute data address from instruction decode 30d or from elsewhere on PLD 10, either upstream (e.g., “ALT ADDR1”) or downstream (e.g., “ALT ADDRM”) from an upstream interface circuit (e.g., 1606a);

2. ID information for controlling interface circuitry 1606 from instruction decode 30d or from elsewhere on PLD 10; and

3. conversion from relative to absolute data addresses upstream from loops 1620/1640/1660 or downstream from those loops.

Consistent with the earlier discussion of automatic conversion of relative addresses to absolute addresses, the ability to automatically convert (e.g., as in FIG. 12A) from relative data addresses to absolute data addresses greatly facilitates writing complex programs for execution by PLDs with processor objects in accordance with this invention. For example, programs can be created as relatively independently-written modules using relative instruction and/or data addresses that do not have to be non-conflicting from module to module. A unique ID value is associated with each module, and appropriate instruction and/or data address offset values are associated with each ID value. Addition of these offset values to the relative instruction and/or data addresses used in each module converts those addresses to absolute addresses that are non-conflicting from module to module. As has been said, this greatly facilitates the writing and debugging of complex programs for the PLDs of this invention.

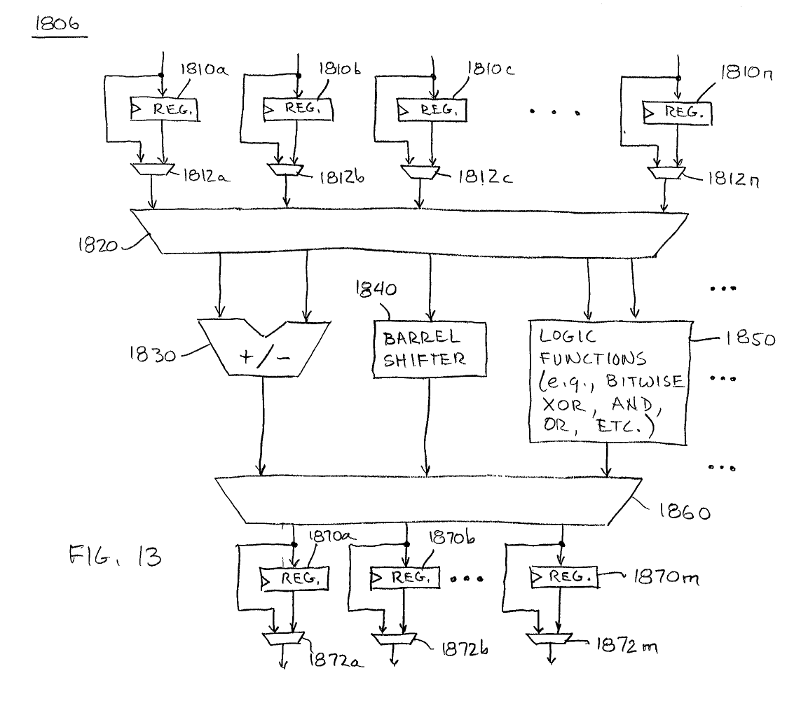

FIG. 13 shows yet another example of an illustrative dedicated operating portion 1806 (analogous, for example, to operating portion 206 in FIG. 1) that can be included in a processor object on a PLD in accordance with this invention. Operating portion 1806 is an example of what may be referred to as an arithmetic logic unit (“ALU”) or arithmetic block. Operating portion 1806 includes a plurality of input data word storage registers 1810a-n. Each of these registers can either be used or bypassed, depending on how the associated PLC 1812 is controlled. PLC 1820 allows selection of any of a wide range of routings of the outputs of PLCs 1812 to functional units 1830, 1840, 1850, etc.

Functional unit 1830 is an adder/subtractor (i.e., a circuit that can either add together or subtract from one another two applied digital signal values). Functional unit 1840 is a barrel shifter (e.g., a circuit that can perform any of several kinds of shifts on the bits of an applied digital signal value). For example, barrel shifter 1840 may be controllable to perform shifts known as “rotate left,” “rotate right,” “logical shift left,” “logical shift right,” and/or any other type of shift by any fixed or selectable number of bit positions. Functional unit 1850 is capable of performing any of several different logic operations, bitwise, on two (or more) applied digital signal values. For example, functional unit 1850 may logically AND each bit of a first input word with the corresponding bit of a second input word to produce an output. Or the logical AND may be of the corresponding bits in more than two input words. As an alternative to AND, any other logical function(s) (e.g., OR, XOR, NAND, NOR, etc.) may be within the capabilities of functional unit 1850 and therefore selectable as the operation(s) performed by that unit. Still other functional units beyond units 1830, 1840, and 1850 may be provided in operating portion 1806. These may be wholly or partly additional instances of the functional units shown, or they may be wholly or partly different types of functional units.

PLC 1860 is controllable to provide any of a wide range of possible routings of the output signals of functional units 1830/1840/1850 to output registers 1870a-m. Any or all of these registers may be bypassed, if desired, via the associated PLC(s) 1872a-m.

As in other circuitry in accordance with this invention, PLCs 1812, 1820, 1860, and 1872 may be controlled in any of several ways (e.g., statically (using FCEs) or more dynamically (using time-varying signals such as instructions from program memory 40/40b)). Similarly, selection of the various functional options that units 1830/1840/1850 are capable of may be controlled in any of several ways (e.g., any of the ways just given as examples for control of PLCs 1812/1820/1860/1872). In other respects, operation and use of operating portion 1806 may be similar to operation and use of other illustrative operating portions described earlier in this specification.

A PLD in accordance with this invention can work in a system with other components that each use local or relative instruction and/or data addresses that may be conflicting as between those components, while the PLD is adapted to automatically convert these addresses to non-conflicting, absolute addresses for use within the PLD. This may be viewed as extension—to a system—of what is discussed earlier relating to conversion on a PLD from local or relative addresses used within programs to absolute addresses used by the processor objects that actually perform those programs. In this case the programs, rather than being resident within the PLD, may be wholly or partly resident in other components in a system that includes the PLD.

FIG. 14 shows an illustrative system 2010 of the type mentioned in the immediately preceding paragraph. System 2010 includes one or more processors 2020a-n and/or other components 2030. (Although other components 2030 could alternatively or additionally perform functions different from those described below in connection with processors 2020, the following discussion will be simplified by sometimes referring only to the processors, thereby treating other components 2030 as generally similar to the processors.) System 2010 also includes PLD 10 and communications bus 2040 for conveying signals between the various components (10/2020/2030) of the system. PLD 10 may include a VLIW or other processor object usable as a slave by other components 2020/2030 in the system. For example, another component 2020/2030 may generate an instruction (e.g., a VLIW instruction) for transmission to PLD 10 via bus 2040 and for execution by the PLD (especially the processor object of the PLD). Components 2020/2030 may use local or relative addresses in their own internal operations, and may generate the above-mentioned instruction also using their own local or relative addresses. In other words, the instruction may be received by PLD 10 with address portions that are local or relative to the other component 2020/2030 that originated it. But these local or relative address may not be distinct from local or relative addresses used by others of components 2020/2030.

To avoid the necessity for having each component 2020/2030 send addresses to PLD 10 that are known to be unique system-wide and specific to the absolute address requirements of PLD 10, the PLD is provided with a data space translation and protection table and related circuitry 2050 for converting relative addresses it receives to absolute addresses it needs for its own operations. A data portion of interface 2050 is to load input data into the PLD 10 processor circuitry and to retrieve processed data from that processor circuitry. A program portion of interface 2050 is to start the correct process, identified by an ID. A typical sequence of processing may be: (1) apply ID to interface 2050; (2) load processor with data, starting at address zero (data address offset corrected internally by ID data address translation); (3) assert START signal so that processor starts based on ID program translation address; (4) wait for DONE interrupt or signal; and (5) unload data from processor using ID. Data can also be loaded and unloaded in some cases by the processor itself, using its I/O ports. In this case, ID may still be required so that the processor knows which program space to run.

Illustrative circuitry for inclusion in component 2050 is shown in more detail in FIG. 15. Circuitry 2050 includes register 2052 for receiving and storing address information as it is received by PLD 10 from bus 2040. The source of the address information (e.g., a component 2020/2030) also supplies to PLD 10 via bus 2040 identifying (“ID”) information that may identify the source (e.g., the other component 2020/2030 and/or the particular routine performed by that other component that is the source of the address information applied to register 2052). Register 2054 receives and stores this ID information for application to translation table 2060.

For each possible ID value, translation table 2060 contains a start address offset value and an end address value. When translation table 2060 receives an ID value, it outputs the associated start address offset value via leads 2061a, and it outputs the end address via leads 2061b. The start address offset value is applied to adder 2062 for addition to the relative address information from register 2052. The result of this addition is the absolute address information that PLD 10 needs to perform its operations. For example, the absolute address information output by adder 2062 may be used by PLD 10 to find a VLIW or other instruction in its instruction memory. As another example, the absolute address information output by adder 2062 may be used to modify information in an instruction received via bus 2040 for performance by PLD 10. Or the address information output by adder 2062 may be used by PLD 10 to find data in its data memories. As long as the ID value remains the same, all successive relative addresses received via register 2052 are modified (using adder 2062) by the start address offset value associated with that ID information.

Each absolute address output by adder 2062 is also applied to compare circuitry 2070 for comparison with the end address information on leads 2061b. If the adder 2062 outputs exceed the permissible end address, then compare circuitry 2070 produces an output signal indicating that an error has occurred.

In connection with the foregoing it will be understood that (analogously to what is shown in FIG. 8A) if the apparatus supports both program and data address translation, separate program and data address translation table circuitry will typically be provided. In what is known as a “Harvard architecture” processor, separate data spaces are provided for program and data storage. (Most RISC and DSP processors have this type of architecture.) In many of the examples given in this specification, the program sequencer addresses the program memory, an instruction fetched from which is then decoded by the instruction decoder. The address generator (or an instruction via the instruction decoder) will address data memory.

If the program memory is relocated when it is loaded into the processor, the processor needs to support two types of address translation “on the fly”. These two types of address translation are (1) an address translation for program addresses (i.e., in the program sequencer), and (2) a further translation table for the data addresses (i.e., out of the instruction decoder and the address generators). The second one is necessary because addressing information embedded in the program will not be correct in absolute terms (i.e., without translation to convert from relative values to correct absolute values). The present specification provides disclosure sufficient to enable those skilled in the art to implement all of these various types of addressing options in circuitry within the scope of this invention.

It will be understood that the use of adder 2062 in FIG. 15 is only illustrative, and that any other logical or arithmetic combination could be performed instead if desired. Also, although FIG. 15 is shown only comparing each absolute address to an end address, it will be understood that more sophisticated absolute address checking could be performed if desired. For example, translation table 2060 might output a permissible address range associated with each ID value, and each absolute address could then be checked to make sure that it is within the permissible range.

From the foregoing it will be seen that circuitry of the type shown in FIGS. 14 and 15 allows each system component that may wish to make use of PLD 10 to work with and output to PLD 10 its own local or relative address information without regard for the possibility that other components 2020/2030 may be using similar (and therefore possibly conflicting) local or relative addresses, and also without regard for the absolute address requirements of PLD 10. PLD 10 takes whatever local or relative address information it receives, and automatically converts that information to the appropriate absolute address information that it needs for its own operations. Users of system 2010 can write software for components 2020/2030 without regard for possible conflicts with software written for other components 2020/2030 (at least insofar as addressing and operation of PLD 10 is concerned) and also without regard for the ultimate absolute address requirements of PLD 10. This greatly facilitates writing and debugging such software.

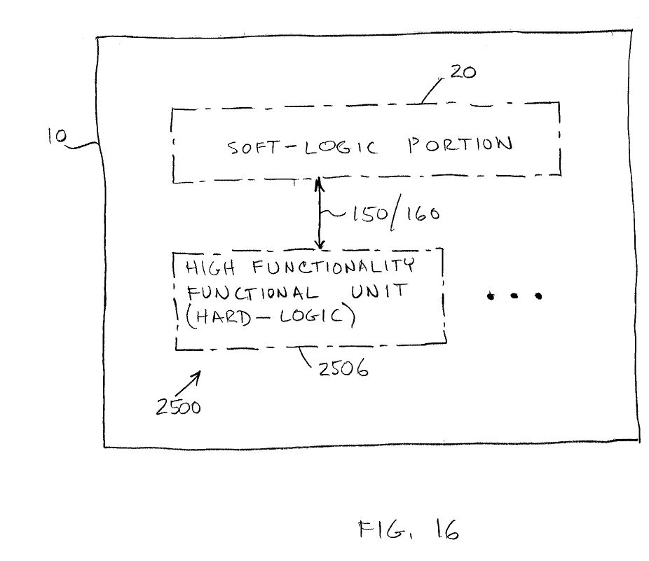

As was noted in the earlier Summary section of this specification, another aspect of the invention relates to providing PLDs with programmable logic and at least partly hard-wired, high functionality, functional units. A high functionality functional unit may be like what is referred to above as the operating portion of a processor object, provided that the operating-portion/functional-unit has more than one function. The inclusion of more than one function accounts for the characterization “high functionality”. Examples of high functionality functional units are (1) a multiplier combined with an adder tree or (2) a multiplier combined with an accumulator. An illustrative embodiment of a PLD 10 as described in this paragraph is shown in FIG. 16.

With further reference to FIG. 16, the illustrative PLD 10 shown there includes soft-logic portion 20, hard-logic portion 2500, and circuitry 150/160 for making connections between those two portions. Hard-logic portion 2500 includes one or more high functionality functional units 2506. The circuitry of each functional unit 2506 is at least partly hard-wired to perform multiple functions such as multiplication and addition or multiplication and accumulation. Some specific examples of circuitry that can be used for a functional unit 2506 are shown in FIG. 2 (operating portion 306), FIG. 3 (operating portion 406), FIG. 4 (operating portion 506), FIG. 5 (operating portion 606), FIG. 6 (operating portions 706a and/or 706b), FIG. 7 (operating portions 906a, 906b, 906c, and/or 906d), and FIG. 13 (operating portion 1806). Thus examples of high functionality functional units include MAC circuitry, ALU circuitry, barrel shifter circuitry, and Galois Field circuitry. Various combinations and/or multiple instances of high functionality functional units can be included.

In embodiments of the invention such as are shown in FIG. 16, the soft-logic portion 20 of the PLD may be programmed to perform certain functions that are performed in the hard-logic portion of earlier-described embodiments. For example, some or all of the functions of the control portion 204 (FIG. 1), 504 (FIG. 4), 604 (FIG. 5), etc. of the hard-logic circuitry in those embodiments may be implemented by appropriately programming the soft-logic portion 20 of embodiments of the type shown in FIG. 16. To give some even more specific examples of this last point, in embodiments of the type shown in FIG. 16 some or all of the functions of address generator 710 and/or program sequencer 720 (FIG. 6) or address generator 910 and/or program sequencer 920 (FIG. 7) may be implemented in soft-logic portion 20.

Although not necessarily the case for all high functionality function units, such units may include the feature that some or all of the functions performed are programmably selectable from a plurality of possible functions. Alternatively or additionally, such units may include the feature that some or all of the functions performed are dynamically selectable from a plurality of possible functions. Examples of high functionality functional units with these capabilities are the operating portions 506 and 606 shown in FIGS. 4 and 5, respectively. To review this point briefly and only partly again, whether adder/subtractor 550 in operating portion 506 adds or subtracts can either be programmably (and therefore statically) controlled from FCE 556 via PLC 554, or more dynamically controlled from a lead 150 signal via PLC 554. In the embodiment shown in FIG. 16 the lead 150 signal referred to in the immediately preceding sentence can come from any suitable source in soft-logic portion 20. For example, it can come from elements in soft-logic portion 20 that have been configured (i.e., programmed) to operate as an instruction decode (e.g., like 30d in FIG. 7) operating in conjunction with other elements in soft-logic portion 20 that have been configured to perform the functions associated in FIG. 7 with program sequencer 920, program memory 40b, instruction unpack 30c, etc.

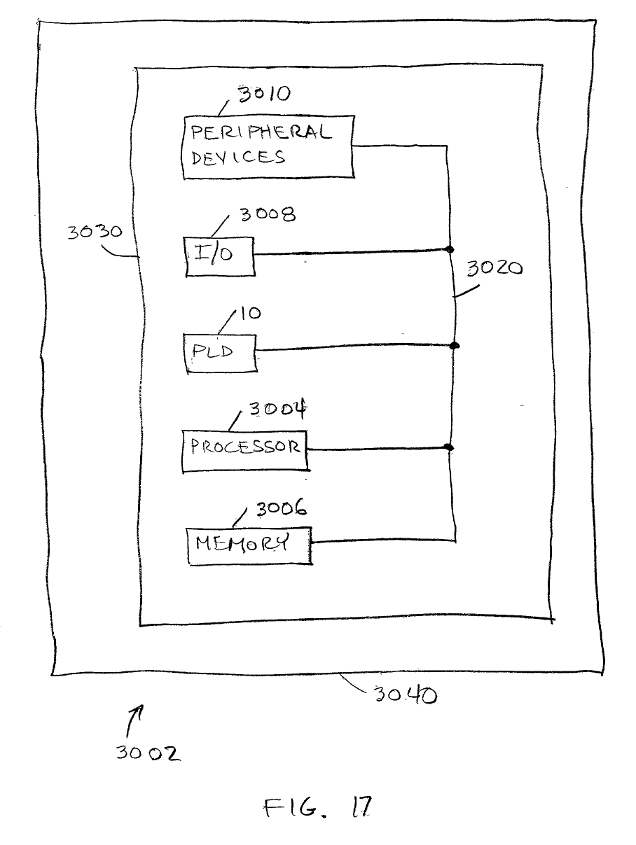

FIG. 17 illustrates a programmable logic device 10 of this invention in a data processing system 3002. Data processing system 3002 may include one or more of the following components: a processor 3004; memory 3006; I/O circuitry 3008; and peripheral devices 3010. These components are coupled together by a system bus 3020 and are populated on a circuit board 3030 which is contained in an end-user system 3040.

System 3002 can be used in a wide variety of applications, such as computer networking, data networking, instrumentation, video processing, digital signal processing, or any other application where the advantage of using programmable or reprogrammable logic is desirable. Programmable logic device 10 can be used to perform a variety of different logic functions. For example, programmable logic device 10 can be configured as a processor or controller that works in cooperation with processor 3004. Programmable logic device 10 may also be used as an arbiter for arbitrating access to a shared resource in system 3002. In yet another example, programmable logic device 10 can be configured as an interface between processor 3004 and one of the other components in system 3002. It should be noted that system 3002 is only exemplary, and that the true scope and spirit of the invention should be indicated by the following claims.

Various technologies can be used to implement programmable logic devices 10 in accordance with this invention, as well as the various components of those devices (e.g., the above-described PLCs and the FCEs that control the PLCs). For example, each PLC can be a relatively simple programmable connector such as a switch or a plurality of switches for connecting any one of several inputs to an output. Alternatively, each PLC can be a somewhat more complex element that is capable of performing logic (e.g., by logically combining several of its inputs) as well as making a connection. In the latter case, for example, each PLC can be product term logic, implementing functions such as AND, NAND, OR, or NOR. Examples of components suitable for implementing PLCs are EPROMs, EEPROMs, pass transistors, transmission gates, antifuses, laser fuses, metal optional links, etc. As has been mentioned, the various components of PLCs can be controlled by various, programmable, function control elements (“FCEs”). (With certain PLC implementations (e.g., fuses and metal optional links) separate FCE devices are not required.) FCEs can also be implemented in any of several different ways. For example, FCEs can be SRAMs, DRAMs, first-in first-out (“FIFO”) memories, EPROMs, EEPROMs, function control registers (e.g., as in Wahlstrom U.S. Pat. No. 3,473,160), ferro-electric memories, fuses, antifuses, or the like. From the various examples mentioned above it will be seen that this invention is applicable to both one-time-only programmable and reprogrammable devices.

It will be understood that the foregoing is only illustrative of the principles of the invention, and that various modifications can be made by those skilled in the art without departing from the scope and spirit of the invention. For example, the various elements of this invention can be provided on a PLD in any desired numbers and arrangements.

The invention claimed is:

1. A programmable logic device comprising:
programmable logic circuitry; and
a processor object including program sequencer circuitry adapted to select instruction information, and an operating portion responsive to the instruction information selected by the program sequencer circuitry.

2. The device defined in claim 1 wherein the processor object further includes address generator circuitry adapted to select data information.

3. The device defined in claim 2 wherein the operating portion is further responsive to the data information selected by the address generator circuitry.

4. The device defined in claim 1 further comprising:
memory circuitry adapted to store the instruction information.

5. The device defined in claim 4 wherein the memory circuitry is part of the programmable logic circuitry.

6. The device defined in claim 2 further comprising:
memory circuitry adapted to store the data information.

7. The device defined in claim 6 wherein the memory circuitry is part of the programmable logic circuitry.

8. The device defined in claim 2 wherein the address generator circuitry is further adapted to generate addresses of destinations for further data information output by the operating portion.

9. The device defined in claim 2 wherein the address generator comprises register file circuitry.

10. The device defined in claim 1 wherein the program sequencer circuitry is further adapted to automatically make a plurality of successive selections of instruction information.

11. The device defined in claim 2 wherein the address generator circuitry is further adapted to make a plurality of concurrent selections of data information.

12. The device defined in claim 1 wherein the processor object further includes register file circuitry adapted to select data information.

13. The device defined in claim 1 wherein the operating portion is selected from the group consisting of MAC circuitry, ALU circuitry, barrel shifter circuitry, and Galois Field circuitry.

14. The device defined in claim 1 wherein the operating portion includes multiple instances of circuitry selected from the group consisting of MAC circuitry, ALU circuitry, barrel shifter circuitry, and Galois Field circuitry.

15. The device defined in claim 1 further comprising:
circuitry adapted to convert instruction information selections that are relative to instruction information addresses that are absolute.

16. The device defined in claim 2 further comprising:
circuitry adapted to convert data information selections that are relative to data information addresses that are absolute.

17. A digital processing system comprising:
processing circuitry;
a memory coupled to said processing circuitry; and
a programmable logic device as defined in claim 1 coupled to the processing circuitry and the memory.

18. A printed circuit board on which is mounted a programmable logic device as defined in claim 1.

19. The printed circuit board defined in claim 18 further comprising:
a memory mounted on the printed circuit board and coupled to the programmable logic device.

20. The printed circuit board defined in claim 18 further comprising:
processing circuitry mounted on the printed circuit board and coupled to the programmable logic device.

21. A system comprising:
a programmable logic device including a processor object; and
circuitry external to the programmable logic device and adapted to apply signals to the programmable logic device for processing by that device, the signals including relative address information referring in relative terms to locations on the programmable logic device, the programmable logic device further including translation circuitry adapted to convert the relative address information to absolute address information identifying actual locations on the programmable logic device.

22. The system defined in claim 21 wherein the signals further include ID information associated with the relative address information, and wherein the translation circuitry is responsive to the ID information.

23. The system defined in claim 21 wherein the translation circuitry comprises:
address offset generation circuitry adapted to produce an address offset value; and
combinational circuitry adapted to combine the relative address information and the address offset value to produce the absolute address information.

24. The system defined in claim 23 wherein the combinational circuitry comprises:
adder circuitry adapted to add the address offset value to the relative address information to produce the absolute address information.

25. The system defined in claim 21 wherein the translation circuitry is further adapted to check validity of the absolute address information.

26. The system defined in claim 25 wherein the translation circuitry comprises compare circuitry adapted to compare the absolute address information to permissible address information.

27. A programmable logic device comprising:
a soft-logic portion including programmable logic circuitry, memory circuitry, and programmable interconnection circuitry; and
a hard-logic portion connected to the soft-logic portion and including processor object circuitry.

28. The device defined in claim 27 wherein the processor object circuitry comprises:
program sequencer circuitry;
address generator circuitry; and operating portion circuitry.

29. The device defined in claim 28 wherein the program sequencer circuitry is adapted to retrieve from the memory circuitry instructions for at least partly controlling operation of the operating portion circuitry.

30. The device defined in claim 28 wherein the address generator circuitry is adapted to retrieve from the memory circuitry data on which the operating portion circuitry operates.

31. The device defined in claim 28 wherein the address generator circuitry is adapted to identify locations in the memory circuitry to receive data output by the operating portion circuitry.

32. The device defined in claim 28 wherein the address generator circuitry comprises multi-ported register file circuitry.

33. The device defined in claim 28 wherein the soft-logic portion is adapted to provide signals for at least partly controlling operation of the program sequencer circuitry.

34. The device defined in claim 33 wherein the signals are indicative of an instruction address for use by the program sequencer circuitry.

35. The device defined in claim 34 wherein the program sequencer circuitry is adapted to respond to the instruction address by producing a succession of identifications of locations in the memory circuitry.

36. The device defined in claim 28 wherein the soft-logic portion is adapted to provide signals for at least partly controlling operation of the address generator circuitry.

37. The device defined in claim 36 wherein the signals are indicative of a data address for use by the address generator circuitry.

38. The device defined in claim 37 further comprising:
interface circuitry adapted to convert the data address to an absolute address in the memory circuitry.

39. The device defined in claim 28 wherein the address generator circuitry is adapted to identify in parallel a plurality of locations in the memory circuitry.

40. The device defined in claim 28 wherein the operating portion circuitry is selected from the group consisting of MAC circuitry, ALU circuitry, barrel shifter circuitry, and Galois Field circuitry.

41. The device defined in claim 28 wherein the operating portion circuitry comprises multiple instances of circuitry selected from the group consisting of MAC circuitry, ALU circuitry, barrel shifter circuitry, and Galois Field circuitry.

42. The device defined in claim 28 wherein the operating portion is adapted to execute a VLIW instruction.

43. The device defined in claim 28 wherein the operating portion is adapted to perform at least one DSP operation.

44. A programmable logic device comprising:
programmable logic circuitry; and
an at least partly hard-wired, high functionality, functional unit adapted to exchange signal information with the programmable logic circuitry.

45. The programmable logic device defined in claim 44 wherein the functional unit is adapted to perform functions selectable from a plurality of functions.

46. The programmable logic device defined in claim 45 wherein the functional unit is programmable to select the functions that it will perform from the plurality of functions.

47. The programmable logic device defined in claim 45 wherein the functional unit is dynamically controllable by a control signal to select the functions that it will perform from the plurality of functions.

48. The programmable logic device defined in claim 47 wherein the programmable logic circuitry is adapted to supply the control signal.

49. The programmable logic device defined in claim 45 wherein the functional unit is programmable to select the functions that it will perform from the plurality of functions based on either a programmable selection or a dynamic control signal selection.

50. The programmable logic device defined in claim 49 wherein the programmable logic circuitry is adapted to supply the control signal.

51. The programmable logic device defined in claim 44 wherein the functional unit is selected from the group consisting of MAC circuitry, ALU circuitry, barrel shifter circuitry, and Galois Field circuitry.

52. The programmable logic device defined in claim 44 wherein the programmable logic circuitry includes memory circuitry.

53. The programmable logic device defined in claim 52 wherein the memory circuitry is adapted to store data for processing by the functional unit.

54. The programmable logic device defined in claim 52 wherein the memory circuitry is adapted to store program instructions for execution at least in part by the functional unit.

55. The programmable logic device defined in claim 53 wherein the programmable logic circuitry is adapted to select data from the memory circuitry for application to the functional unit.

56. The programmable logic device defined in claim 54 wherein the programmable logic circuitry is adapted to select program instructions from the memory circuitry for execution by the functional unit.

57. The programmable logic device defined in claim 56 wherein the programmable logic circuitry is further adapted to use an instruction selected from the memory circuitry to at least partly control selection of data on which the functional unit operates.

58. The programmable logic device defined in claim 56 wherein the programmable logic circuitry is further adapted to use an instruction selected from the memory circuitry to at least partly control functions performed by the functional unit.
